(19) United States
(12) Patent Application Publication
(10) Pub. No.: US 2011/0180688 A1
(43) Pub. Date: Jul. 28, 2011

(54) PHOTOELECTRIC CONVERTER AND PROCESS FOR PRODUCING THE SAME AND SOLID STATE IMAGING DEVICE

(75) Inventor: Ken Nakahara, Kyoto (JP)

(73) Assignee: ROHM CO., LTD., Kyoto (JP)

(21) Appl. No.: 13/010,289

(22) Filed: Jan. 20, 2011

(30) Foreign Application Priority Data
Jan. 22, 2010 (JP) 2010-012527

(51) Int. Cl. H01L 27/146; H01L 31/18; H01L 31/0296

(52) U.S. Cl. 250/208.1; 438/95; 257/43; 257/E31.027; 257/E31.015; 257/E27.133

(57) ABSTRACT

A photoelectric converter includes: a lower electrode layer; a compound semiconductor thin film of chalcopyrite structure disposed on the lower electrode layer and having a high-resistivity layer in its surface; a transparent electrode layer disposed on the compound semiconductor thin film; an interlayer insulating layer; a zinc-oxide-based compound semiconductor thin film; and electrodes. With application of a reverse bias voltage between the transparent electrode layer and the lower electrode layer, and application of a bias voltage between the electrodes, the photoelectric converter photoelectrically converts ultraviolet region light. Thus, the photoelectric converter achieves photoelectric conversion of light in a wider region. Such a photoelectric converter and a process for producing the same, and a solid state imaging device to which the photoelectric converter is applied are provided.

### CROSS REFERENCE TO RELATED APPLICATIONS AND INCORPORATION BY REFERENCE

This application is based upon and claims the benefit of prior Japanese Patent Application P2010-12527 filed on Jan. 22, 2010; the entire contents of which are incorporated by reference herein.

### BACKGROUND OF THE INVENTION

1. Field of the Invention

The present invention relates to a photoelectric converter and a process for producing the same and a solid state imaging device. More particularly, the present invention relates to: a photoelectric converter which includes a photoelectric conversion unit having a compound semiconductor film of chalcopyrite structure and is capable of acquiring imaging data by receiving light in even a wavelength range which cannot be photoelectrically converted by the compound semiconductor film of chalcopyrite structure; a process for producing the photoelectric converter; and a solid state imaging device.

2. Description of the Related Art

There is a thin film solar cell including a light absorbing layer made of a CuInSe₂ semiconductor thin film of chalcopyrite structure including a group Ib element, a group Mb element and a group VIb element (CIS-based thin film), or a Cu(In, Ga)Se₂ semiconductor thin film containing Ga in a solid state (CIGS-based thin film). Such thin film solar cell shows high energy conversion efficiency and has an advantage that efficiency degradation due to light irradiation and the like is low.

The semiconductor thin film of chalcopyrite structure, i.e., the CIS-based thin film or the CIGS-based thin film containing Ga in a solid state is generally formed at the temperature of 550° C. from a viewpoint of prevention of degradation of film quality and increase in leakage current. It has heretofore been considered that the film formation at a lower temperature than 550° C. makes the film have particles small in diameter and have poorer dark current characteristics. Note that the heat resistance limit of a semiconductor integrated circuit is about 400° C.

There has already been disclosed a photoelectric converter using a compound semiconductor thin film of chalcopyrite structure and configured to considerably reduce dark current, and a process for producing the same (see, e.g., Patent Document 1: Japanese Patent Application Publication No. 2007-123720 and Patent Document 2: Japanese Patent Application Publication No. 2007-123721).

Also, there has already been disclosed a method for forming a high-quality CIGS-based thin film by selenization treatment (see, e.g., Patent Document 3: U.S. Pat. No. 5,436,204 and Patent Document 4: U.S. Pat. No. 5,441,897).

Meanwhile, there has already been disclosed a solid state imaging element in which switching elements each including a thin film transistor are formed on a substrate and are stacked with a sensor region formed of an amorphous semiconductor layer while pixel electrodes connected to the switching elements are interposed in between, or a solid state imaging element having the substrate formed of an insulating substrate (see, e.g., Patent Document 5: Japanese Patent Application Publication No. 2001-144279).

Since the solid state imaging element disclosed in Patent Document 4 uses the amorphous semiconductor layer as a photosensor area, a photoelectric conversion wavelength thereof is mainly in a visible light wavelength range.

In such a conventional solid state imaging element, since a low electric field is applied to a photoelectric conversion film to detect electric charges, the photoelectric conversion film itself has no multiplication function.

### SUMMARY OF THE INVENTION

Currently, focusing on high optical absorption coefficients of the CIS-based thin film and the CIGS-based thin film and their characteristics of having high sensitivity over a wide wavelength range from visible light to near infrared light, the compound semiconductor thin film material is considered to be used for an image sensor for a security camera (a camera for sensing the visible light during the day and sensing the near infrared light at night), a personal authentication camera (a camera for personal authentication with near infrared light which is not affected by outside light) or an in-vehicle camera (a camera mounted in a car for visual aid at night, distant visual field securing, etc.). However, the CIS-based thin film and the CIGS-based thin film are not sensitive to light on the short wavelength side, i.e., ultraviolet light despite their high sensitivity over a wide wavelength range from visible light to near infrared light. For this reason, the CIS-based thin film and the CIGS-based thin film are not sufficient to obtain images over a wider wavelength range.

It is an object of the present invention to provide a photoelectric converter and a process for producing the same and a solid state imaging device, using a chalcopyrite semiconductor to enable photoelectric conversion of light in a wider wavelength range, thus enabling more imaging data to be acquired.

In order to achieve the above object, the present invention provides a photoelectric converter including: a circuit portion formed on a substrate; a lower electrode layer disposed on the circuit portion; a first photoelectric conversion layer formed of a compound semiconductor thin film of chalcopyrite structure and disposed on the lower electrode layer; a transparent electrode layer disposed on the first photoelectric conversion layer; an interlayer insulating layer formed on the transparent electrode layer; electrodes formed on the interlayer insulating layer; and a second photoelectric conversion layer formed of a zinc-oxide-based compound semiconductor thin film formed on the electrodes and electrically connected to the electrodes. In the photoelectric converter, the lower electrode layer, the first photoelectric conversion layer, the transparent electrode layer, the interlayer insulating layer, and the second photoelectric conversion layer are sequentially stacked on the circuit portion, and with application of a reverse bias voltage between the transparent electrode layer and the lower electrode layer and between the electrodes, the second photoelectric conversion layer photoelectrically converts ultraviolet region light and the first photoelectric conversion layer photoelectrically converts light having a wavelength longer than that of the ultraviolet region.

Moreover, the present invention provides a process for producing a photoelectric converter including: a first step of maintaining a substrate temperature at a first temperature and maintaining a composition ratio of (Cu/(In+Ga)) at 0 in an excessive state of group III elements; a second step of changing the substrate temperature to a second temperature higher than the first temperature, maintaining the second temperature, and shifting the excessive state of group III elements to an excessive state of Cu elements in which the composition ratio of (Cu/(In+Ga)) is not less than 1.0; and a third step of shifting the excessive state of Cu elements in which the composition ratio of (Cu/(In+Ga)) is not less than 1.0 to an excessive state of the group III elements in which the composition ratio of (Cu/(In+Ga)) is not more than 1.0. In the process for producing a photoelectric converter, the third step includes a first period in which the substrate temperature is maintained at the second temperature, and a second period in which the substrate temperature is changed from the second temperature to a third temperature lower than the first temperature and maintained at the third temperature, so that the compound semiconductor thin film of chalcopyrite structure is formed.

Further, the present invention provides a solid state imaging device including: a circuit portion formed on a substrate; lower electrode layers disposed on the circuit portion and separated from each other between pixels adjacent to each other in one of a column direction and a row direction; first photoelectric conversion layers each formed of a compound semiconductor thin film of chalcopyrite structure, disposed on the respective lower electrode layers, and separated from each other between the adjacent pixels in one of the column direction and the row direction; a transparent electrode layer disposed on the first photoelectric conversion layers and having a planarized structure over the adjacent pixels; an interlayer insulating layer formed on the transparent electrode layer; electrodes formed on the interlayer insulating layer; and second photoelectric conversion layers each formed of a zinc-oxide-based compound semiconductor thin film formed on the electrodes and electrically connected to the electrodes. In the solid state imaging device, the lower electrode layers, the first photoelectric conversion layers, the transparent electrode layer, the interlayer insulating layer, and the second photoelectric conversion layers are sequentially stacked on the circuit portion, and each of the second photoelectric conversion layers photoelectrically converts ultraviolet region light and a corresponding one of the first photoelectric conversion layers photoelectrically converts light having a wavelength longer than that of the ultraviolet region, with application of a reverse bias voltage between the transparent electrode layer and a corresponding one of the lower electrode layers and between the corresponding electrodes.

Still further, the present invention provides a solid state imaging device including: a plurality of word lines WLᵢ (where i=1 to m, and m is an integer) disposed in a row direction; a plurality of bit lines BLⱼ (where j=1 to n, and n is an integer) disposed in a column direction; photodiodes including lower electrode layers, respectively, compound semiconductor thin films of chalcopyrite structure disposed on the lower electrode layers, respectively, and a transparent electrode layer disposed on the compound semiconductor thin films; and pixels disposed at intersections of the plurality of word lines WLᵢ and the plurality of bit lines BLⱼ. In the solid state imaging device, the lower electrode layers, the compound semiconductor thin films and the transparent electrode layer are sequentially stacked, and with application of a reverse bias voltage between the transparent electrode layer and each of the lower electrode layers, impact ionization is caused in a corresponding one of the compound semiconductor thin films of chalcopyrite structure, and thereby induces the multiplication of charges generated by photoelectric conversion.

The present invention includes the first photoelectric conversion layer using the chalcopyrite semiconductor and the second photoelectric conversion layer formed of the zinc-oxide-based compound semiconductor thin film. Thus, the present invention enables sensing of light having wavelengths ranging from the ultraviolet light region to the visible light region and further to the near infrared region, thereby enabling sufficient imaging data to be acquired.

### BRIEF DESCRIPTION OF DRAWINGS

FIG. 1 is an overall schematic plane pattern configuration diagram of a solid state imaging device formed by two-dimensionally arranging photoelectric converters according to a first embodiment of the present invention.

FIG. 2 is a schematic cross-sectional structure diagram of the photoelectric converter according to the first embodiment of the present invention.

FIG. 3 is a diagram showing a more detailed cross-sectional structure example including adjacent pixels of the solid state imaging device formed by two-dimensionally arranging the photoelectric converters according to the first embodiment.

FIG. 4 is a diagram showing another more detailed cross-sectional structure example including adjacent pixels of the solid state imaging device formed by two-dimensionally arranging the photoelectric converters according to the first embodiment.

FIG. 5 is a diagram showing a cross-section of an ultraviolet light detecting element using a second photoelectric conversion layer.

FIG. 6 is a diagram showing a plane of the ultraviolet light detecting element using the second photoelectric conversion layer.

FIG. 7 is a diagram showing another configuration example of the ultraviolet light detecting element using the second photoelectric conversion layer.

FIG. 8 is a graph showing spectral sensitivity characteristics and light transmittance of the second photoelectric conversion layer.

FIG. 9 is a chart showing a relationship between a band-gap-equivalent wavelength and a Mg content ratio in MgZnO.

FIG. 10 is a chart showing multiple sensitivity curves of a ZnO-based photoelectric conversion element and a solar spectrum.

FIG. 11A is a schematic cross-sectional structure diagram of a photoelectric conversion unit and FIG. 11B is a schematic cross-sectional structure diagram of a compound semiconductor thin film part, in the photoelectric converter according to the first embodiment of the present invention.

FIG. 12A is a configuration diagram of the compound semiconductor thin film which forms a pin junction and FIG. 12B is an electric field strength distribution diagram corresponding to FIG. 12A, in the photoelectric conversion unit formed by a process for producing the photoelectric converter according to the first embodiment of the present invention.

FIG. 13 is a characteristic diagram showing a relationship between a signal current Iₛⱼ (A) and a target voltage Vₜ (V) applied between an upper electrode layer and a lower electrode layer in the photoelectric converter according to the first embodiment of the present invention.

FIG. 14 is a schematic diagram of current-voltage characteristics for explaining a multiplication phenomenon in the case with light irradiation and in the case without light irradiation, in the photoelectric converter according to the first embodiment of the present invention.

FIGS. 15A and 15B are detailed explanation diagrams of a step of forming a compound semiconductor thin film of chalcopyrite structure in a process for producing a photoelectric converter according to a comparative example of the present invention, FIG. 15A showing a substrate temperature in each stage and components during film formation, FIG. 15B showing a composition ratio of (Cu/(In+Ga)) in each stage.

FIG. 16 is a schematic cross-sectional structure diagram of a photoelectric conversion unit in the photoelectric converter formed by the process for producing the photoelectric converter according to the comparative example of the present invention.

FIGS. 17A and 17B are detailed explanation diagrams of a step of forming a compound semiconductor thin film of chalcopyrite structure in the process for producing the photoelectric converter according to the first embodiment of the present invention, FIG. 17A showing a substrate temperature in each stage and components during film formation, FIG. 17B showing a composition ratio of (Cu/(In+Ga)) in each stage.

FIG. 18 is a schematic cross-sectional structure diagram of a photoelectric conversion unit in the photoelectric converter formed by the process for producing the photoelectric converter according to the first embodiment of the present invention.

FIG. 19A shows a relationship between dark current density (A/cm²) and a Cu/group III ratio as a result of applying the process for producing the photoelectric converter to a test structure, and FIG. 19B shows an SEM photograph of an example of the test structure having Mo and CIGS stacked on a substrate.

FIG. 20 shows an analysis result obtained by SIMS on the photoelectric conversion unit formed by the process for producing the photoelectric converter according to the comparative example of the present invention.

FIG. 21 shows an analysis result obtained by SIMS on the photoelectric conversion unit formed by the process for producing the photoelectric converter according to the first embodiment of the present invention.

FIG. 22 shows a wavelength characteristic of quantum efficiency using, as a parameter, the value of Cu/group III ratio of the compound semiconductor thin film (CIGS thin film) formed by the process for producing the photoelectric converter according to the first embodiment of the present invention.

FIG. 23 shows a wavelength characteristic of the quantum efficiency of the photoelectric converter according to the first embodiment of the present invention.

FIG. 24 is an optical absorption characteristic diagram of the photoelectric converter according to the first embodiment of the present invention.

FIG. 25 is a dependence characteristic graph between band gap energy and In/(In+Ga) composition ratio of the compound semiconductor thin film of chalcopyrite structure applied to the photoelectric converter according to the first embodiment of the present invention.

FIG. 26 shows a relationship between the dark current and a surface layer formation temperature T_{A} of the photoelectric converter formed by the process for producing the photoelectric converter according to the first embodiment of the present invention.

FIG. 27A shows an SCM photograph of the photoelectric conversion unit formed by the process for producing the photoelectric converter according to the comparative example of the first embodiment of the present invention, and FIG. 27B is an explanatory diagram of FIG. 27A.

FIG. 28A shows an SCM photograph of the photoelectric conversion unit formed by the process for producing the photoelectric converter according to the first embodiment of the present invention, and FIG. 28B is an explanatory diagram of FIG. 28A.

FIG. 29 is a schematic cross-sectional structure diagram of one pixel part of the solid state imaging device configured by application of the photoelectric converter according to the first embodiment of the present invention.

FIG. 30A is a circuit configuration diagram of one pixel of the solid state imaging device configured by application of the photoelectric converter according to the first embodiment of the present invention. FIG. 30B is a circuit configuration diagram of one pixel of the solid state imaging device according to the comparative example of the present invention

FIG. 31 is a schematic circuit block diagram of the solid state imaging device configured by application of the photoelectric converter according to the first embodiment of the present invention.

FIG. 32 is a schematic cross-sectional structure diagram of a photoelectric converter according to a second embodiment of the present invention.

FIG. 33 is a schematic cross-sectional structure diagram of one pixel part of a solid state imaging device configured by application of the photoelectric converter according to the second embodiment of the present invention.

FIG. 34 is a cross-sectional structure diagram in a case where a color filter is provided in the solid state imaging device shown in FIG. 3.

FIG. 35 is a cross-sectional structure diagram in a case where a color filter is provided in the solid state imaging device shown in FIG. 4.

### DETAILED DESCRIPTION OF THE INVENTION

Next, embodiments of the present invention will be described with reference to the drawings. Note that, in the following description of the drawings, the same or similar parts will be denoted by the same or similar reference numerals. However, it should be noted that the drawings are schematic and different from actual ones. Moreover, the drawings may include portions each having dimensional relationships and ratios different from one drawing to another.

### First Embodiment

(Plane Pattern Configuration)

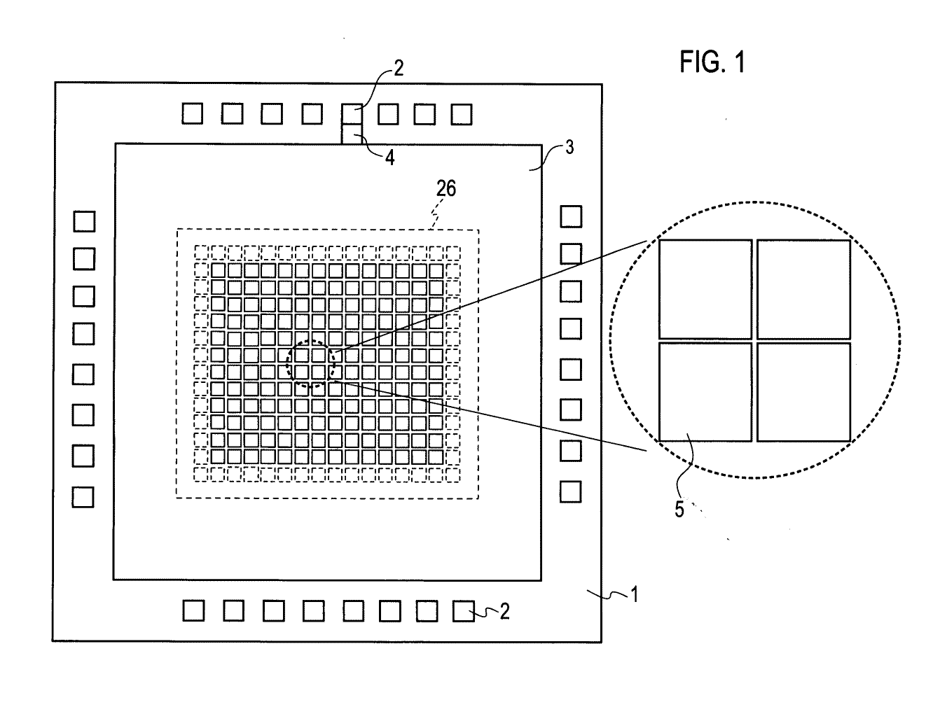

FIG. 1 shows an overall schematic plane pattern configuration of a solid state imaging device formed by two-dimensionally arranging photoelectric converters according to a first embodiment of the present invention. As shown in FIG. 1, the solid state imaging device includes: a package substrate 1; multiple bonding pads 2 disposed in a peripheral part on the package substrate 1; and an aluminum electrode layer 3 which is connected to one of the bonding pads 2 by a bonding pad connector 4, and is connected along the peripheral part of the solid state imaging device to a transparent electrode layer 26 disposed on pixels 5 of the solid state imaging device. Specifically, the aluminum electrode layer 3 covers an edge region of the transparent electrode layer 26, and is connected to one of the bonding pads 2 by the bonding pad connector 4. Moreover, the pixels 5 are arranged in a matrix pattern in the example shown in FIG. 1.

(Photoelectric Converter)

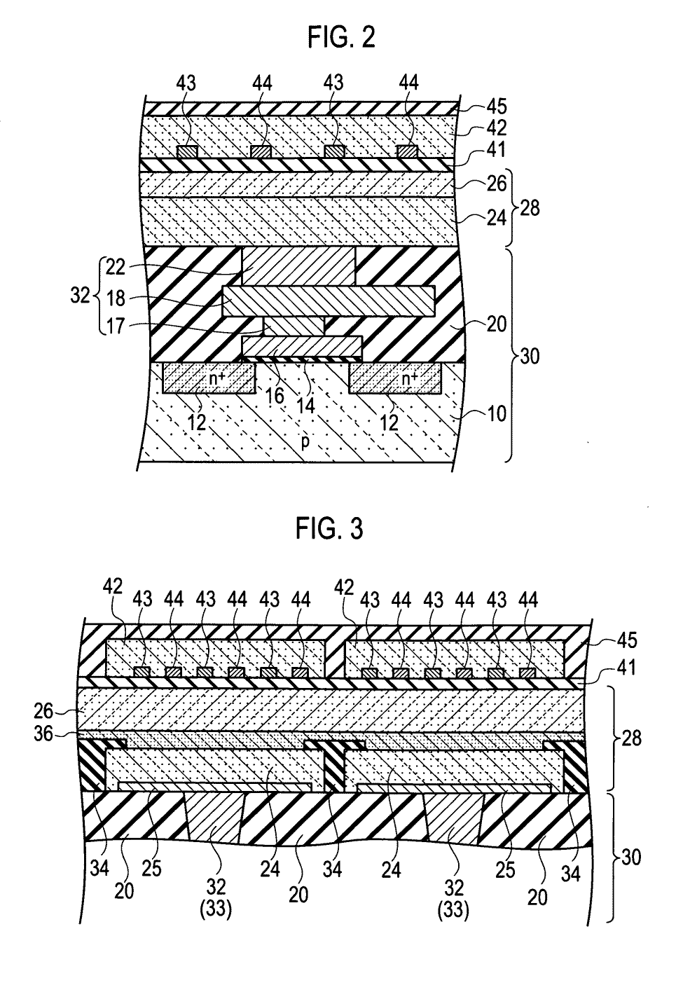

FIG. 2 shows a schematic cross-sectional structure of the photoelectric converter according to the first embodiment. As shown in FIG. 2, the photoelectric converter includes: a circuit portion 30 formed on a substrate; and a photoelectric conversion unit 28 disposed on the circuit portion 30. Note that FIG. 2 omits illustration of a lower electrode layer 25 and a buffer layer 36.

The photoelectric converter shown in FIG. 2 includes: the circuit portion 30 formed on a semiconductor substrate 10; the lower electrode layer 25 disposed on the circuit portion 30; a compound semiconductor thin film 24 of chalcopyrite structure disposed on the lower electrode layer 25; the buffer layer 36 disposed on the compound semiconductor thin film 24; and the transparent electrode layer 26 disposed on the buffer layer 36.

The lower electrode layer 25, the compound semiconductor thin film 24, the buffer layer 36 and the transparent electrode layer 26 are sequentially stacked on the circuit portion 30.

In the photoelectric converter according to the first embodiment, a reverse bias voltage is applied between the transparent electrode layer 26 and the lower electrode layer 25 to cause impact ionization in the compound semiconductor thin film 24 of chalcopyrite structure, so that the multiplication of charges generated by photoelectric conversion is induced.

The circuit portion 30 includes a transistor having a gate connected to the lower electrode layer 25.

The circuit portion 30 may be integrated with the lower electrode layer 25, the compound semiconductor thin film 24, the buffer layer 36 and the transparent electrode layer 26, which are sequentially stacked on the circuit portion 30.

In the photoelectric converter shown in FIG. 2, the compound semiconductor thin film 24 of chalcopyrite structure is formed of Cu(In_{X}, Ga_{1-X})Se₂(0≦X≦1).

As the lower electrode layer 25, molybdenum (Mo), niobium (Nb), tantalum (Ta), tungsten (W), or the like can be used, for example.

As a material to form the buffer layer 36, CdS, ZnS, ZnO, ZnMgO, ZnSe, In₂S₃ or the like can be used, for example.

The transparent electrode layer 26 is formed of a non-doped ZnO film (i-ZnO) disposed on the compound semiconductor thin film 24, and an n-type ZnO film disposed on the non-doped ZnO film (i-ZnO).

The photoelectric converter shown in FIG. 2 can also be configured as a photosensor having sensitivity also in a near infrared light region.

The compound semiconductor thin film 24 includes a high-resistivity layer (i-type CIGS layer) on its surface.

The circuit portion 30 may include a complementary metal oxide semiconductor field effect transistor (CMOSFET), for example.

FIG. 2 shows an n-channel MOS transistor which constitutes a part of a CMOS in the circuit portion 30. The circuit portion 30 includes: the semiconductor substrate 10; source/drain regions 12 formed in the semiconductor substrate 10; a gate insulating film 14 disposed on the semiconductor substrate 10 between the source/drain regions 12; a gate electrode 16 disposed on the gate insulating film 14; a VIA0 electrode 17 disposed on the gate electrode 16; a wiring layer 18 for gates disposed on the VIA0 electrode 17; and a VIA1 electrode 22 disposed on the wiring layer 18.

The gate electrode 16, the VIA0 electrode 17, the wiring layer 18, and the VIA1 electrode 22 are all formed in an interlayer insulating film 20.

A VIA electrode 32 disposed on the gate electrode 16 is formed of the VIA0 electrode 17, the wiring layer 18 disposed on the VIA0 electrode 17, and the VIA1 electrode 22 disposed on the wiring layer 18.

In the photoelectric converter shown in FIG. 2, the photoelectric conversion unit 28 and the gate electrode 16 of the n-channel MOS transistor which constitutes a part of the CMOS are electrically connected to each other by the VIA electrode 32 disposed on the gate electrode 16.

Since an anode of a photodiode which constitutes the photoelectric conversion unit 28 is connected to the gate electrode 16 of the n-channel MOS transistor, optical information detected in the photodiode is amplified by the n-channel MOS transistor.

Note that the circuit portion 30 can also be formed using a thin film transistor having a CMOS configuration formed on a thin film formed on a glass substrate, for example.

FIG. 3 shows a more detailed cross-sectional structure including adjacent pixels of the solid state imaging device formed by two-dimensionally arranging the photoelectric converters according to the first embodiment.

As is clear from FIG. 3, the lower electrode layer 25 and the compound semiconductor thin film 24 disposed on the lower electrode layer 25 in a pixel cell are separated from those in another pixel cell adjacent thereto by an element isolation region 34 formed of an interlayer insulating film. Moreover, the buffer layer 36 disposed on the compound semiconductor thin film 24 is integrally formed all over the semiconductor substrate surface. Also, the transparent electrode layer 26 is integrally formed all over the semiconductor substrate surface, and is made electrically common.

Note that the compound semiconductor thin film 24 and the lower electrode layer 25 may have the same width, or more specifically, as shown in FIG. 3, the compound semiconductor thin film 24 may be set to have a larger width than the lower electrode layer 25.

The configuration described above can prevent leakage while filling a void or a pinhole generated in an underlying CIGS thin film with a semi-insulating layer by providing a non-doped ZnO film (i-ZnO) as the transparent electrode layer 26. Therefore, the dark current on the pn junction interface can be reduced by increasing the thickness of the non-doped ZnO film (i-ZnO).

Also, the configuration having the buffer layer 36 has been described above as an embodiment. Although the leakage current can be reduced by the buffer layer 36, the present invention is not limited thereto but is applicable to a configuration in which an electrode layer is provided, without the buffer layer, on the compound semiconductor thin film (CIGS) layer.

Meanwhile, the present invention uses a structure to which a second photoelectric conversion layer is added to achieve a wider band. Specifically, a photoelectric conversion layer is laminated, which is formed of a zinc-oxide-based compound semiconductor thin film (ZnO-based thin film) that is a different material from that of the photoelectric conversion layer formed of the CIGS. The ZnO-based thin film is completely transparent to visible light, and thus does not hinder imaging in the visible and near infrared regions even though the ZnO-based thin film is formed on the CIGS layer for photoelectric conversion in the visible light and near infrared light range.

FIG. 8 shows spectral sensitivity characteristics and light transmittance of the ZnO-based thin film. In FIG. 8, the horizontal axis represents the wavelength (nm), the vertical axis on the left side represents the light reception sensitivity (A/W), and the vertical axis on the right side indicates the transmittance (%). The light reception sensitivity is expressed by a ratio of an amount of light (watt) incident on the element to a photocurrent (ampere) flowing through the element. The amount of incident light is measured as 16 μW/cm². ZnO PD indicates a ZnO-based photoelectric conversion element, while Si PD indicates a conventional PN-type silicon photoelectric conversion element. PE represents light transmittance of PEDOT:PSS, while ZnO represents light transmittance of the ZnO substrate. Also, TH represents a theoretical curve of the light reception sensitivity.

Further, the ultraviolet light region is divided into sections of ultraviolet light A (having a wavelength longer than 320 nm and not longer than 400 nm), ultraviolet light B (having a wavelength longer than 280 nm and not longer than 320 nm) and ultraviolet light C (having a wavelength not longer than 280 nm), as shown in FIG. 8. PEDOT:PSS shows the transmittance of 80% or more particularly in the sections of ultraviolet light A and ultraviolet light B of the ultraviolet light region having the wavelength not longer than 400 nm. Thus, it is found out that PEDOT:PSS is excellent in transmittance. In the section of ultraviolet light C, the transmittance drops radically as the absorption attributable to C—C bond (C is carbon) in an organic material increases. Moreover, ZnO to be the semiconductor photoelectric conversion layer has transmittance of 60% or more in the visible light region having the wavelength exceeding 400 nm, but the transmittance drops radically once the wavelength reaches 400 nm. The transmittance reaches approximately 0 below the wavelength of 400 nm.

Meanwhile, in the range exceeding the wavelength of 400 nm, the ZnO-based photoelectric conversion element is less than 10⁻² A/W and reaches approximately 0, which is the noise level of the measuring device, as is clear from an S/N ratio of the data. On the other hand, particularly in the wavelength regions of ultraviolet light A and ultraviolet light B below the wavelength of 400 nm, high sensitivity of 10⁻² A/W or more is achieved, which is higher than that of the conventional Si PD. Therefore, it is found out that, in the ZnO to be the semiconductor photoelectric conversion layer, photoelectric conversion is performed with high efficiency in the wavelength regions of ultraviolet light A and ultraviolet light B, while almost no photoelectric conversion occurs in the visible light region. That is, the ZnO-based photoelectric conversion element functions as a visible light-blind ultraviolet photodetector.

As shown in FIGS. 2 and 3, a ZnO-based compound semiconductor thin film 42 to be the second photoelectric conversion layer is formed. For distinction from the photocurrent obtained by the photoelectric conversion in the CIGS layer, an interlayer insulating layer 41 is formed between the ZnO-based compound semiconductor thin film 42 and the transparent electrode layer 26.

After the transparent electrode layer 26 is formed, the interlayer insulating layer 41 made of SiN, SiO₂, Al₂O₃ or the like is formed by plasma CVD or the like. Among these materials, one having high transmittance in the visible and near infrared regions is preferable so as not to hinder the reception of light in the visible and near infrared regions in the CIGS layer. For this reason, SiO₂ or Al₂O₃ is more preferable than SiN which is easily colored, for the interlayer insulating layer 41.

After the interlayer insulating layer 41 is formed, metal electrodes 43 and 44 are formed. These metal electrodes 43 and 44 are to extract the photocurrent generated by the photoelectric conversion in the ZnO-based compound semiconductor thin film 42. For the metal electrodes 43 and 44, positive and negative metal electrodes are formed in one step. The metal electrodes 43 and 44 each have a comb shape, and are formed so that strip-shaped portions thereof are alternately arranged. The interval between the strip-shaped portions and the width of each of the strip-shaped portions of the metal electrodes can be set appropriately in accordance with the intended use. Moreover, the metal electrodes 43 and 44 are preferably formed of ultrathin noble metal, TiN or the like to prevent oxidation of the metal electrodes, which may be caused by the ZnO-based compound semiconductor thin film 42 to be subsequently formed.

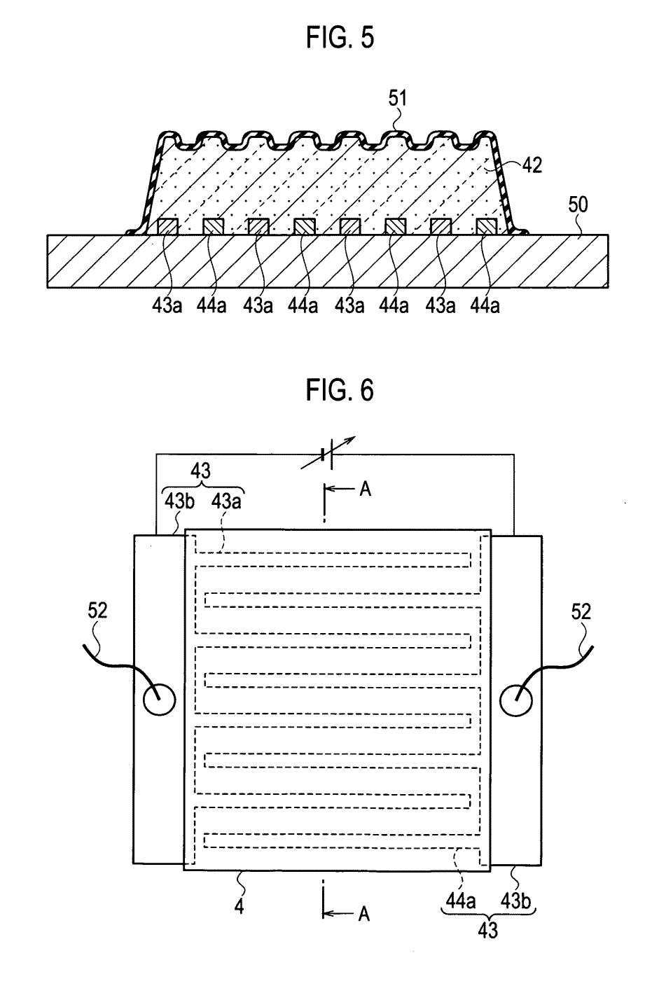

Here, FIGS. 5 and 6 show in detail a relationship between the ZnO-based compound semiconductor thin film 42 and the metal electrodes 43 and 44 shown in FIGS. 2 to 4. FIGS. 5 and 6 show a structure in which the metal electrodes 43 and 44 and the ZnO-based compound semiconductor thin film 42 are formed not on the interlayer insulating layer 41 but on a substrate 50. This structure can be used as an ultraviolet light detecting element.

FIG. 6 is a plan view of the ultraviolet light detecting element when seen from above, and FIG. 5 shows a cross-section taken along the A-A line in FIG. 6. Note that, for simplicity, FIG. 6 shows a state where a protective film 51 is removed.

The metal electrodes 43 and 44 are formed on the substrate 50. The metal electrode 44 corresponds to the negative electrode when the metal electrode 43 is the positive electrode, while the metal electrode 44 corresponds to the positive electrode when the metal electrode 43 is the negative electrode. As shown in FIG. 6, the metal electrodes 43 and 44 are formed to have a comb shape. The comb-shaped metal electrode 43 includes detection electrode parts 43a which are strip-shaped and an extraction electrode part 43b which is a common portion. In the extraction electrode part 43b, the multiple detection electrode parts 43a are integrally formed. Meanwhile, the comb-shaped metal electrode 44 also includes detection electrode parts 44a which are strip-shaped and an extraction electrode part 44b which is a common portion. In the extraction electrode part 44b, the multiple detection electrode parts 44a are integrally formed. The detection electrode parts 43a and the detection electrode parts 44a are alternately arranged in such a manner as not to overlap with each other.

Here, the detection electrode parts 43a and 44a corresponding to the strip-shaped portions of the comb-shaped electrodes may be configured in an alternately nested fashion. The detection electrode parts 43a and 44a need not have a rectangular shape but may be formed into a wave-like shape to have curved portions. Moreover, the detection electrode parts 43a and 44a may be formed to have round tips. Furthermore, as to the detection electrode parts 43a and 44a, an electrode width thereof need not be fixed, and a distance between the electrodes need not be fixed. Those including all the above configurations are called the strip-shaped detection electrode parts in the present invention.

On the metal electrodes 43 and 44, the ZnO-based compound semiconductor thin film 42 is stacked, which is a second photoelectric conversion layer as well as an ultraviolet light absorbing layer. The ZnO-based compound semiconductor thin film 42 absorbs ultraviolet light to generate electrons and holes. Here, the detection electrode parts 43a and 44a to directly detect carriers by coming into contact with the ZnO-based compound semiconductor thin film 42 are buried in the ZnO-based compound semiconductor thin film 42.

As seen from FIG. 5, surfaces of the detection electrode parts 43a and 44a in contact with the ZnO-based compound semiconductor thin film 42 in the regions of the metal electrodes 43 and 44 are formed to be entirely covered with the ZnO-based compound semiconductor thin film 42 and thus not to be exposed. Moreover, the ZnO-based compound semiconductor thin film 42 is provided on a part of each of the extraction electrode parts 43b and 44b on the side closer to the detection electrode parts 43a and 44a. In this way, a configuration is achieved in which no electrodes are disposed on the surface of the ZnO-based compound semiconductor thin film 42.

On the extraction electrode parts 43b and 44b, wires 52 are bonded in the regions not covered with the ZnO-based compound semiconductor thin film 42. The extraction electrode parts 43b and 44b are electrode portions to extract, to the outside, a current based on the electrons and holes generated by the ZnO-based compound semiconductor thin film 42 absorbing the ultraviolet light. The current is extracted to the outside through the wires 52. For this reason, a direct-current power supply is connected between the metal electrodes 43 and 44 as shown in FIG. 6 since a direct-current bias needs to be applied therebetween. The bias voltage is designed to be variable. Note that, in order to extract the detection current to the outside, the metal electrodes 43 and 44 may be die-bonded with solder to external connection electrodes or the like without using the wires 52.

As a material which has high-resistivity and selectively absorbs only the ultraviolet light, the ZnO-based compound semiconductor thin film 42 is used. In this embodiment, Mg_{X}Zn_{1-X}O (0≦X≦0.7) is used as a ZnO-based compound semiconductor.

Meanwhile, for the substrate 50, a high-resistivity transparent material which does not absorb ultraviolet light and does not cause any unnecessary current is preferable, and glass, for example, can be used. For the protective film 51, a material such as SiN and SiO₂ which has a water-proof function, a moisture-proof function, a scratch-proof function, or the like is used. Generally, SiN has better waterproof performance and is thus often used. However, since the ZnO-based compound semiconductor thin film 42 is used to absorb the ultraviolet light for detection, SiN which is easily colored is not preferable, and thus SiO₂ is preferably used. Note that the protective film 51 need not be formed.

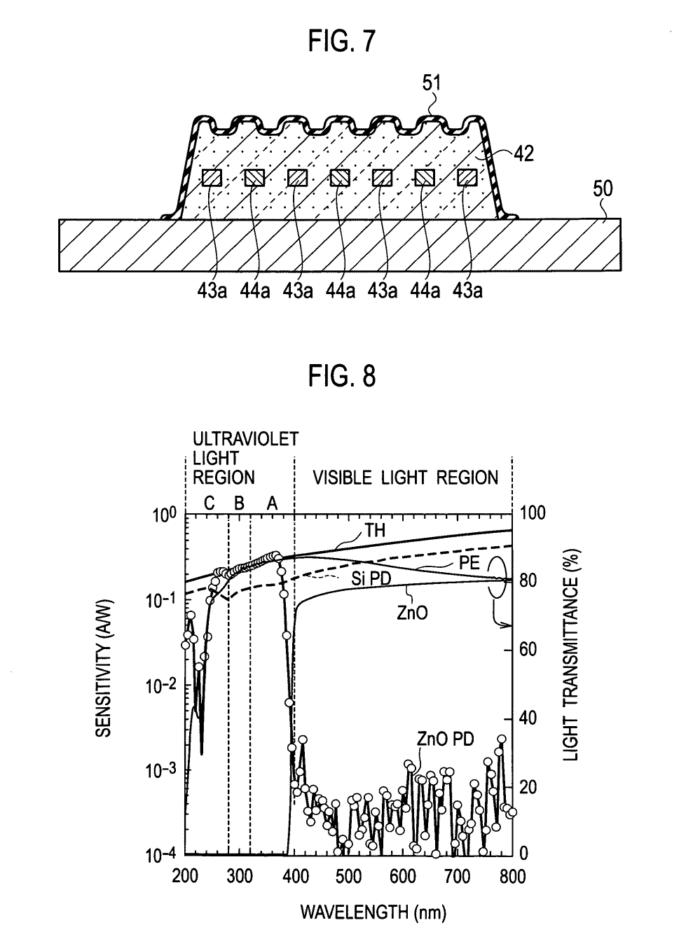

Furthermore, the metal electrodes 43 and 44 are arranged to come into contact with the substrate 50, and the detection electrode parts 43a and 44a and the like are buried in the ZnO-based compound semiconductor thin film 42. However, a configuration shown in FIG. 7 may be adopted. Specifically, in the configuration shown in FIG. 7, the detection electrode parts 43a and 44a are wrapped around with the ZnO-based compound semiconductor thin film 42. In this case, since the electrodes can be arranged on the film surface side where more light is absorbed, a larger photoinduced current is achieved. Moreover, since the electrodes are distant from the dissimilar interface (glass/ZnO), variation factors are reduced.

After the formation of the metal electrodes 43 and 44, the ZnO-based compound semiconductor thin film 42 is formed. The ZnO-based material can be formed by sputtering, MOCVD or the like. Here, the film formation is preferably performed by sputtering in order to form the film in a temperature range where the circuit portion is not damaged. In this embodiment, Mg_{X}Zn_{1-X}O (0≦X≦0.7) is used as the ZnO-based material. The ZnO-based compound semiconductor thin film 42 can be formed by any of reactive sputtering of Mg metal, sputtering using a sintered target, and co-sputtering of MgO+ZnO. In order to make the composition easily adjustable in accordance with the intended use and to reduce oxygen loss which is likely to cause a problem in the ZnO-based material, co-sputtering of MgO+ZnO is most preferable.

After the formation of the ZnO-based compound semiconductor thin film 42, pixels are formed by dry etching or wet etching. In this event, it is preferable that the ZnO-based compound semiconductor thin film 42 has the same pixel size as the compound semiconductor thin film 24. When the ZnO-based compound semiconductor thin film 42 is formed to have the area larger than that of the compound semiconductor thin film 24, there arises a problem of an increased chip size. Moreover, although the ZnO-based compound semiconductor thin film 42 is transparent to visible light or near infrared light, light even in a small amount is reflected on the surface of the ZnO-based compound semiconductor thin film 42, thus reducing the amount of light to be made incident on the compound semiconductor thin film 24. For this reason, when the ZnO-based compound semiconductor thin film 42 is formed to have the area smaller than the compound semiconductor thin film 24, there arises a problem that the region where the ZnO-based compound semiconductor thin film 42 is disposed is darker than the other regions.

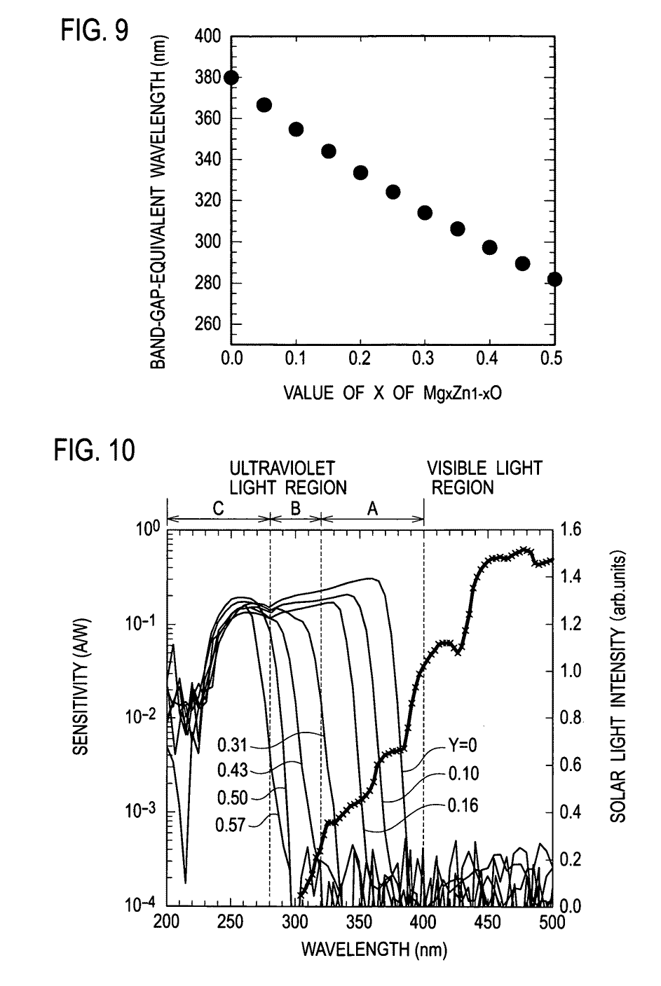

FIGS. 9 and 10 show relationships in the sensitivity regions in a case of using Mg_{X}Zn_{1-X}O (0≦X≦0.7) as the ZnO-based compound semiconductor thin film 42.

FIG. 9 is a chart showing a relationship between a value of X in Mg_{X}Zn_{1-X}O and a band-gap-equivalent wavelength (nm) relative to an Mg content ratio. The band-gap-equivalent wavelength is related to an absorption wavelength point (nm) of the semiconductor. The larger the value of X, the shorter the absorption wavelength of Mg_{X}Zn_{1-X}O. As can be seen from FIG. 9, a light reception sensitivity region of the ultraviolet light detecting element can be changed by changing the Mg content ratio X in Mg_{X}Zn_{1-X}O. Moreover, the amount of ultraviolet light can be discriminated between different wavelength regions, i.e., an ultraviolet light region A and an ultraviolet light region B, by aligning two ultraviolet light detecting elements made of MgZnO and ZnO, respectively, or by aligning two ultraviolet light detecting elements different in Mg content ratio X. Furthermore, only an amount of light in a specific wavelength range can be calculated by subtracting the amount of ultraviolet light detected in one region from that in the other region.

FIG. 10 shows sensitivity curves and the solar spectrum in the atmosphere in a case where a value of Y in Mg_{Y}Zn_{1-Y}O of the ZnO-based compound semiconductor thin film 42 is changed. In FIG. 10, the horizontal axis represents the wavelength (nm), the vertical axis on the left side represents the light reception sensitivity (A/W), and the vertical axis on the right side represents the solar light intensity (arbitrary unit). The larger the value of Y in Mg_{Y}Zn_{1-Y}O, in other words, the larger the Mg composition, the shorter the photoelectric conversion start wavelength of the ZnO-based photoelectric conversion element. As a result, the element becomes no longer sensitive to the long-wavelength region of the ultraviolet light.

Next, the ZnO-based compound semiconductor thin film 42 and the metal electrodes 43 and 44 are configured to have ohmic contact with each other. In this embodiment, portions of the detection electrode parts 43a and 44a and the extraction electrode parts 43b and 44b with which the ZnO-based compound semiconductor thin film 42 comes into contact form the ohmic contact.

When the ZnO-based compound semiconductor thin film 42 and the metal electrodes 43 and 44 are in ohmic contact with each other, a detection current and a voltage at the time when the amount of ultraviolet light is increased or reduced are in a direct proportional relationship forming linearity. However, in the case of Schottky contact, the detection current and the voltage are not in a proportional relationship. Thus, the detection current proportional to the amount of ultraviolet light cannot be obtained. Furthermore, when there is a changeover point between ON and OFF of ultraviolet light in a region where the detection current is hardly changed, it is difficult to make a distinction between ON and OFF. Therefore, it is important to have ohmic contact so that a difference in amount of ultraviolet light is measured based on the amount of detection current, in particular.

Moreover, not only the ohmic contact but also the following can be defined in consideration of factors such as resistance to peel-off. When Mg_{X}Zn_{1-X}O (0≦X≦0.7) is used for the ZnO-based compound semiconductor thin film 42, it is required to use an electrode material having a work function of not less than 4.3 eV and not more than 5.2 eV for the metal electrodes 43 and 44.

Furthermore, when Mg_{X}Zn_{1-X}O (0≦X≦0.7) is used to form the ZnO-based compound semiconductor thin film 42 by sputtering as described above, a structure having no particular crystalline orientation is obtained. The structure having no particular crystalline orientation means a structure other than a structure in which all crystal axes are aligned like single crystal, and includes a polycrystalline structure, an amorphous (non-crystal) structure, and the like.

The structure having no particular crystalline orientation as described above has the following effects. For example, a distortion occurs due to a difference in lattice constant between a substrate and a ZnO-based compound layer or between laminated semiconductor layers in a semiconductor having a wurtzite structure such as a ZnO-based compound. Such a distortion causes a piezoelectric field (electric field caused by a stress). This piezoelectric field becomes a problem particularly when the layers are laminated in a c-axis direction. The problem of the piezoelectric field or the like is not favorable, since ultraviolet light detection current characteristics are affected by such a problem. On the other hand, the structure having no particular crystalline orientation is preferable, since such a piezoelectric field does not occur.

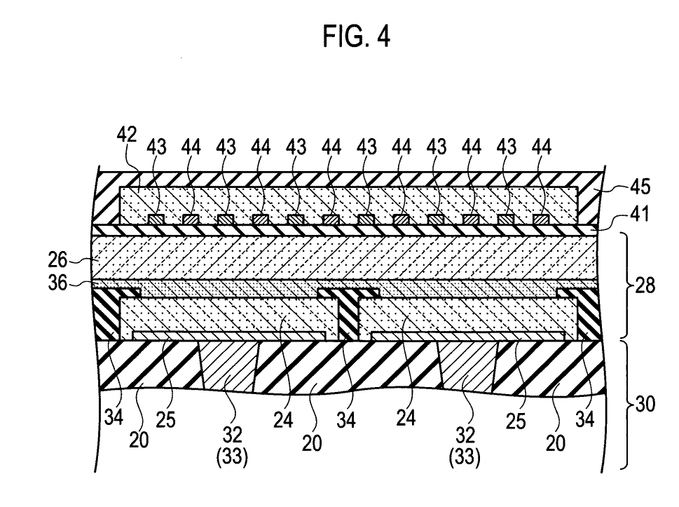

From the reasons described above, the ZnO-based compound semiconductor thin film 42 is formed to have the same pixel size as the compound semiconductor thin film 24, in FIG. 3. However, the ZnO-based compound semiconductor thin film 42 may be formed as shown in FIG. 4, when the compound semiconductor thin film 24 having one pixel size is configured to detect red (R) light, the ZnO-based compound semiconductor thin film 42 corresponding to the next pixel is configured to detect green (G) light, the ZnO-based compound semiconductor thin film 42 corresponding to the subsequent pixel is configured to detect blue (B) light, and thereby the R, G and B light can be detected. In FIG. 4, the ZnO-based compound semiconductor thin film 42 is formed to cover the entire region in which the compound semiconductor thin films 24 corresponding to the three R, G and B pixels are put together. This is because of the following reason. Specifically, since the ZnO-based compound semiconductor thin film 42 is to detect ultraviolet light and has nothing to do with visible light, light reception sensitivity can be improved by allowing all ultraviolet light incident on the R, G and B regions to be received.

(Multiplication Mechanism of Photoelectric Conversion Unit)

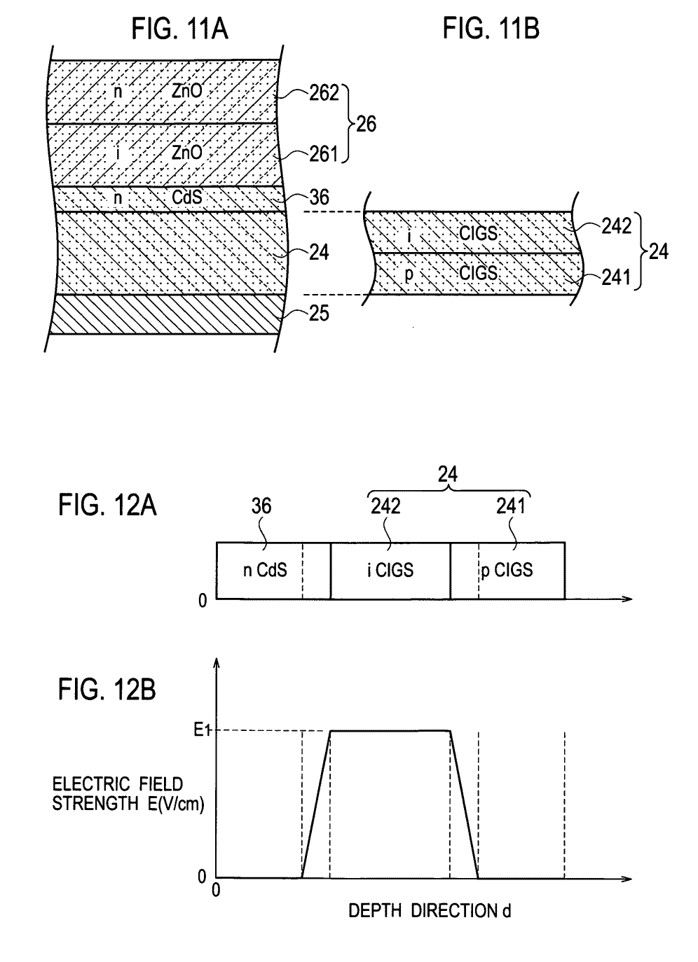

As shown in FIG. 11A, the photoelectric conversion unit 28 of the photoelectric converter according to the first embodiment includes: the lower electrode layer 25; the compound semiconductor thin film 24 disposed on the lower electrode layer 25; the buffer layer 36 disposed on the compound semiconductor thin film 24; a semi-insulating layer (iZnO layer) 261 disposed on the buffer layer 36; and an upper electrode layer (nZnO layer) 262 disposed on the semi-insulating layer (iZnO layer) 261.

The configuration described above can prevent leakage while filling a void or a pinhole generated in the underlying CIGS thin film 24 with a semi-insulating layer by providing the semi-insulating layer 261 made of a non-doped ZnO layer as the transparent electrode layer 26. However, the present invention is not limited thereto but the ZnO layer formed of the semi-insulating layer (iZnO layer) 261 and the upper electrode layer (nZnO layer) 262 can also be formed of only the upper electrode layer (nZnO layer) 262.

Moreover, an i-type CIGS layer (high-resistivity layer) 242 is formed on the interface which comes into contact with the buffer layer 36 of the compound semiconductor thin film 24. As a result, since an underlying CIGS thin film 241 is a p-type, a pin junction is formed, which includes the p-type CIGS layer 241, the i-type CIGS layer 242, and the n-type buffer layer (CdS) 36 as shown in FIGS. 11A and 11B.

The leakage due to a tunnel current which occurs when the conductive upper electrode layer 262 is brought into direct contact with the CIGS thin film 24 can be prevented by the structure formed of the upper electrode layer (nZnO layer) 262, the semi-insulating layer (iZnO layer) 261, the buffer layer 36, the i-type CIGS layer 242, the p-type CIGS layer 241 and the lower electrode layer 25. Also, the dark current can be reduced by increasing the thickness of the semi-insulating layer 261 made of the non-doped ZnO layer.

The thickness of the upper electrode layer 262 is, for example, about 500 nm. The thickness of the semi-insulating layer 261 is, for example, about 200 nm. The thickness of the buffer layer 36 is, for example, about 100 nm. The thickness of the i-type CIGS layer 242 is, for example, about 200 nm to 600 nm. The thickness of the p-type CIGS layer 241 is, for example, about 1 μm to 2 μm. The thickness of the lower electrode layer 25 is, for example, about 600 nm. The whole thickness from the lower electrode layer 25 to the transparent electrode layer 26 is, for example, about 3 μm.

Moreover, as the transparent electrode layer 26, other electrode materials are also applicable. For example, an ITO film, a tin oxide (SnO₂) film, or an indium oxide (In₂O₃) film can be used.

FIG. 12A is a configuration diagram of the compound semiconductor thin film which forms a pin junction in the photoelectric conversion unit 28 of the photoelectric converter according to the first embodiment of the present invention, and FIG. 12B is a electric field strength distribution diagram corresponding to FIG. 12A.

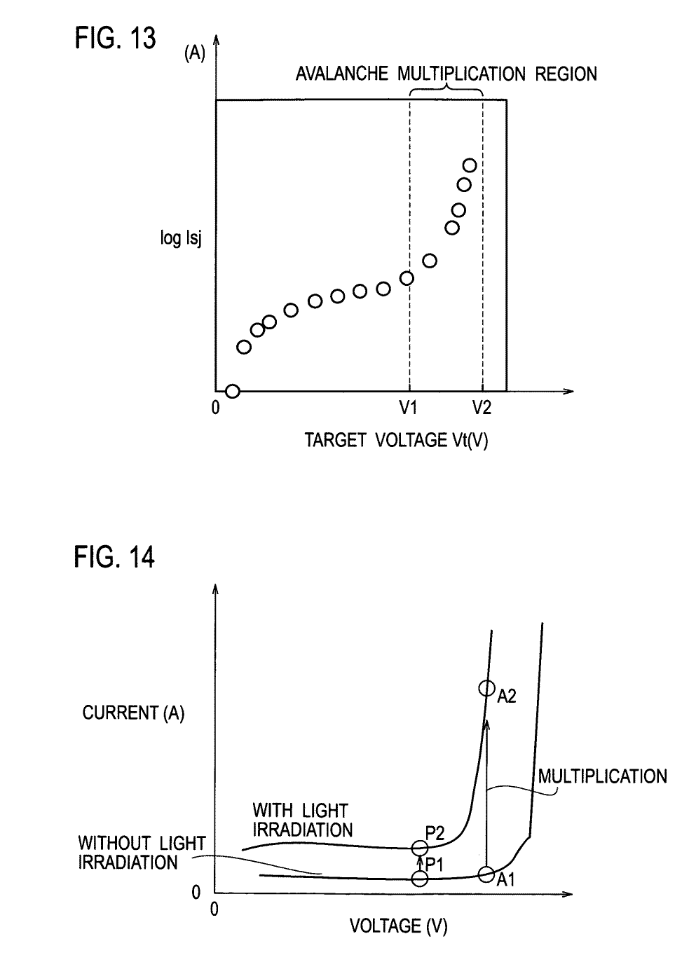

Moreover, FIG. 13 is a diagram for explaining avalanche multiplication. The vertical axis represents a signal current Iₛⱼ (A), and the horizontal axis represents a target voltage Vₜ(V) to be applied between the upper electrode layer and the lower electrode layer. In the avalanche multiplication, the signal current is increased dramatically as the target voltage is increased. Accordingly, the sensitivity of the sensor can be improved.

In the photoelectric converter according to the first embodiment, the target voltage Vₜ equivalent to a reverse bias voltage of pin junction is applied between the upper electrode layer 262 made of n-type ZnO and the lower electrode layer 25 having ohmic contact with the p-type CIGS layer 241.

Since the peak value E1 of the electric field strength E (V/cm) is obtained in the interface of pin junction as shown in FIGS. 12A and 12B, a strong electric field is generated inside the compound semiconductor thin film 24.

In the above structure, the value of the peak value E1 of the electric field strength E (V/cm) is about 4×10⁴ to 4×10⁵ (V/cm). The value of E1 is changed according to the CIGS composition and film thickness of the compound semiconductor thin film 24.

In this case, the avalanche multiplication region in FIG. 13 is about 10V region as the target voltage Vₜ. On the other hand, in order to obtain avalanche multiplication, about 100V is necessary in the case of a normal silicon device.

FIG. 14 shows current-voltage characteristics for explaining a multiplication phenomenon in the case with light irradiation and in the case without light irradiation, in the photoelectric converter according to the first embodiment. As is clear from FIG. 14, there is a slight change in the current value between the case with light irradiation P2 and the case without light irradiation P1 in the state where a relatively low target voltage Vₜ is applied. On the other hand, there is a very significant change in the current value between the case with light irradiation A2 and the case without light irradiation A1 in the state where a relatively high voltage is applied and the avalanche multiplication may occur. The dark current in the case without light irradiation is substantially the same in P1 and A1. Therefore, it is obvious that the S/N ratio is also improved in the photoelectric converter according to the first embodiment.

(Step of Forming Compound Semiconductor Thin Film of Chalcopyrite Structure)

The compound semiconductor thin film of chalcopyrite structure which functions as a light absorbing layer can be formed by a vacuum deposition method called a physical vapor deposition (PVD) method, a sputtering method or a molecular beam epitaxy (MBE) method on a semiconductor substrate or a glass substrate in which the circuit portion 30 is formed. Here, the PVD method means a method for forming a film by depositing raw materials evaporated in vacuum.

When the vacuum deposition method is used, respective components (Cu, In, Ga, Se and S) of the compound are used as separate vapor deposition sources and vapor-deposited on the substrate in which the circuit portion 30 is formed.

In the sputtering method, a chalcopyrite compound is used as a target or each of the components is individually used as a target.

Note that since the substrate is heated to high temperature to form the compound semiconductor thin film of chalcopyrite structure on the glass substrate in which the circuit portion 30 is formed, a compositional shift may occur due to separation of a chalcogenide element. In this case, Se or S can be replenished by performing heat treatment for about 1 to several hours at the temperature of 400° C. to 600° C. in a Se or S vapor atmosphere after film formation (selenization treatment or sulfurization treatment).

Next, a production process according to a comparative example of the present invention is first described for reference.

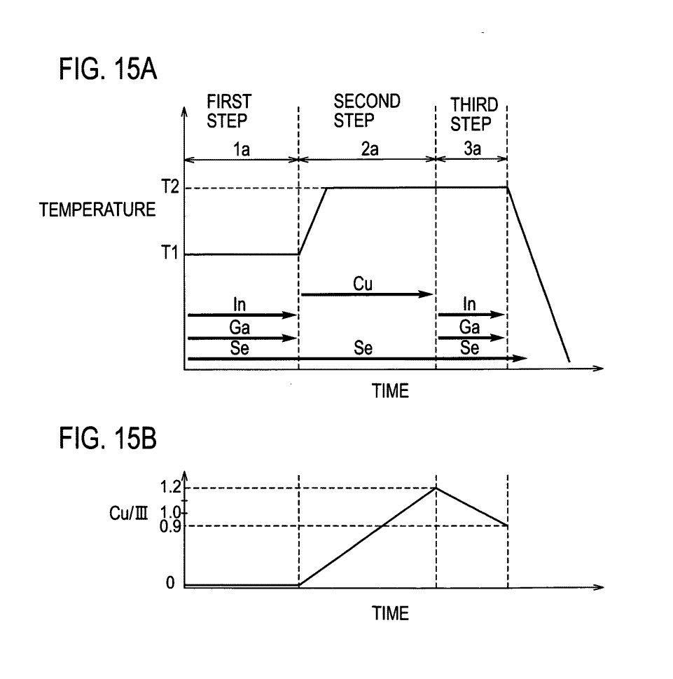

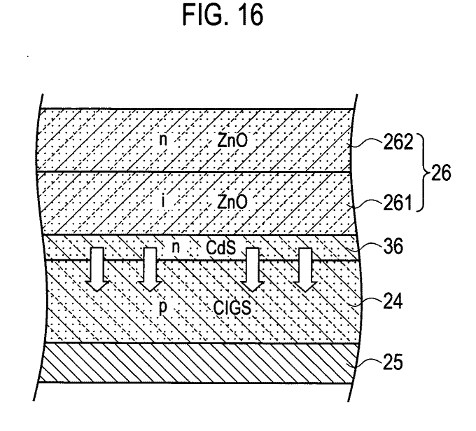

A step of forming the compound semiconductor thin film of chalcopyrite structure applied to the process for producing the photoelectric converter according to the comparative example of the present invention is represented as a three-step method shown in FIGS. 15A and 15B, for example.

When the sputtering method, for example, is used to form a p-type CIGS thin film (Cu(In_{X}, Ga_{1-X})Se₂(0≦X≦1)) subjected to composition control, the film formation is performed in three steps, a first step, a second step and a third step, for example, as shown in FIGS. 15A and 15B. FIG. 15A shows the substrate temperature in each step and the components in the film formation using the sputtering method. FIG. 15B shows a composition ratio of (Cu/group III (In+Ga)) in each step.

First, in the first step, the composition ratio of (Cu/group III (In+Ga)) is maintained at 0 in an excessive state of the group III elements.

Next, the process moves to the second step where the composition ratio of (Cu/group III (In+Ga)) is shifted from 0 to 1.0 or more, i.e., an excessive state of Cu elements.

Thereafter, the process moves to the third step where the composition ratio of (Cu/group III (In+Ga)) is shifted from 1.0 or more, i.e., the excessive state of Cu elements, to 1.0 or less, i.e., an excessive state of group III elements. Then, the compound semiconductor thin film of desired chalcopyrite structure (Cu(In_{X}, Ga_{1-X})Se₂ (0≦X≦1)) is formed. In contrast, in this embodiment, the formation of the compound semiconductor thin film 24 is performed at about 400° C. or lower. When the substrate temperature is high enough, each of the constituent elements can be interdiffused.

FIG. 16 is a schematic cross-sectional structure diagram of a photoelectric conversion unit formed by the process for producing the photoelectric converter according to the comparative example of the present invention. According to the process for producing the photoelectric converter according to the comparative example of the present invention, since there is significant diffusion of Cd from the buffer layer 36, the n-type CIGS layer (not shown) formed by the Cd diffusion layer on the buffer layer 36 side of the compound semiconductor thin film 24.

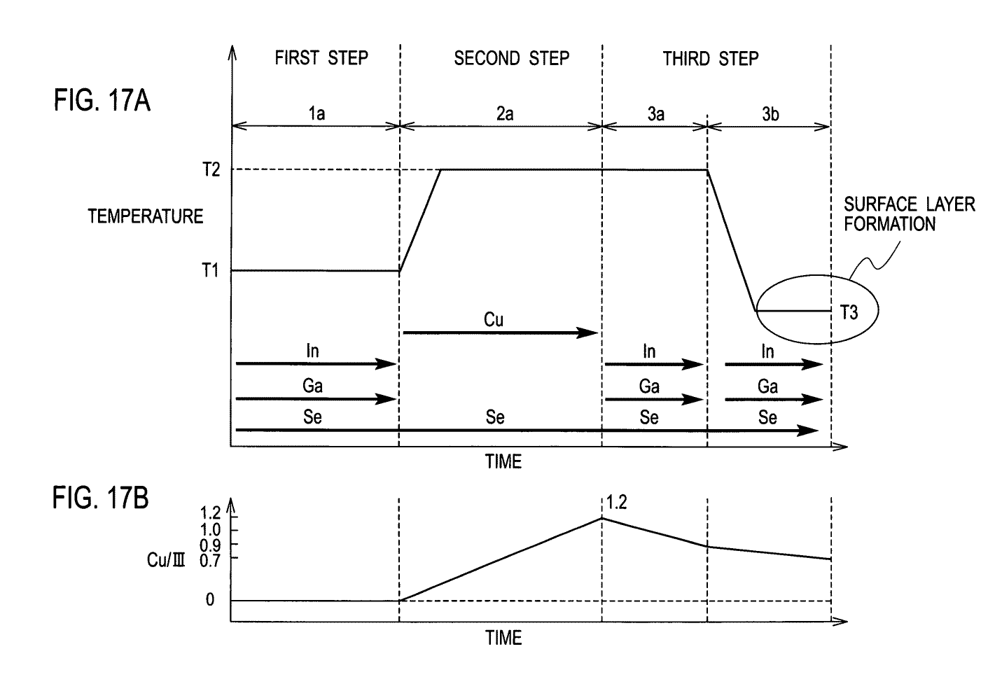

FIGS. 17A and 17B are detailed explanation diagrams of the step of forming the compound semiconductor thin film of chalcopyrite structure in the process for producing the photoelectric converter according to the first embodiment, showing the substrate temperature in each step and the components in the film formation using the vapor deposition method. The film formation may be performed using the sputtering method.

As shown in FIGS. 17A and 17B, the process for producing the photoelectric converter according to the first embodiment includes: a first step (period 1a) of maintaining the substrate temperature at a first temperature T1 and maintaining the composition ratio of (Cu(In+Ga)) at 0 in the excessive state of group III elements; a second step (period 2a) of maintaining the substrate temperature at a second temperature T2 higher than the first temperature T1, and shifting the composition ratio of (Cu/(In+Ga)) to 1.0 or more, i.e., the excessive state of Cu elements; and a third step of shifting the composition ratio of (Cu/(In+Ga)) from 1.0 or more, i.e., the excessive state of Cu elements, to 1.0 or less, i.e., the excessive state of group III elements. The third step includes the first period (period 3a) in which the substrate temperature is maintained at the second temperature T2, and the second period (period 3b) in which the substrate temperature is changed from the second temperature T2 to the third temperature T3 lower than the first temperature T1 and maintained at the third temperature T3, so that the compound semiconductor thin film of chalcopyrite structure is formed.

The compound semiconductor thin film of chalcopyrite structure is formed of Cu(In_{X}, Ga_{1-X})Se₂(0≦X≦1).

The third temperature T3 is in the range from about 300° C. to 400° C., for example.

The second temperature T2 is about 550° C. or lower, for example.

Moreover, in the third step, (Cu/(In+Ga)) at the completion of the first step (period 3a) may be set within a range of about 0.5 to 1.3, for example, and (Cu/(In+Ga)) at the completion of the second step (period 3b) may be set to a value of 1.0 or less.

The compound semiconductor thin film 24 has the i-type CIGS layer 242 on the surface.

In the process for producing the photoelectric converter according to the first embodiment, although the first and second steps are the same as those in the comparative example shown in FIG. 15A, the third step is divided into the two steps, including the period 3a that is a high temperature process step of the temperature T2, and the period 3b in which the process is shifted to a low temperature process step of the temperature T3. Accordingly, the i-type CIGS layer 242 is actively formed on the surface of the compound semiconductor thin film 24. The substrate temperature is 300° C. to 400° C., and is set to about 300° C., for example.

In the process for producing the photoelectric converter according to the first embodiment, the respective constituent elements are not vapor-deposited at the same time, but the vapor deposition thereof is performed in three steps. Thus, distribution of the constituent elements in the film can be controlled to some extent. The beam flux of In and Ga elements is used to control the band gap of the compound semiconductor thin film 24. On the other hand, the Cu/group III (In+Ga) ratio can be used to control the Cu concentration in the CIGS film. The setting of the Cu/group III (In+Ga) ratio is relatively easy. The control of the film thickness is also easy. Se is always supplied in a fixed amount.

Since the setting of the Cu/group III (In+Ga) ratio is relatively easy, the i-type CIGS layer 242 can be easily formed on the surface of the compound semiconductor thin film 24 with good control of the film thickness while reducing the Cu/group III (In+Ga) ratio in the third step. The i-type CIGS layer 242 is considered to function as the i-layer since the Cu concentration thereof which adjusts a carrier concentration in the film is low and the layer has a small number of carriers.

Note that although, with reference to FIGS. 17A and 17B, the description has been given of the example in which the low-temperature step 3b is performed subsequent to the three-step method shown in FIGS. 15A and 15B, the present invention is not limited thereto. For example, the process can be terminated once the three-step method is performed, and then a desired CIGS surface layer can be formed by reducing a Cu fraction while changing the temperature to the temperature as described in the period 3b shown in FIGS. 17A and 17B. Moreover, although the three-step method has been described as an example, the present invention is not limited thereto. For example, the present invention can also be implemented using a bi-layer method. The bi-layer method is a method for forming the CIGS film by, for example, an evaporation method, the sputtering method or the like, using four elements of Cu, In, Ga, and Se in the first step, and then using three elements of In, Ga, and Se except for Cu in the following second step. After forming the film by the bi-layer method, a desired CIGS surface layer can be formed by reducing the Cu fraction while changing the temperature to the temperature as described in the period 3b shown in FIGS. 17A and 17B. As a matter of course, the present invention can also be implemented by further performing the low-temperature film formation step described above on the CIGS thin film formed by use of any other film formation method (a sulfurization method, a selenization/sulfurization method, a simultaneous deposition method, an in-line simultaneous deposition method, a high-speed solid phase selenization method, an RR (roll-to-roll) method, an ionized deposition RR method, a simultaneous deposition RR method, an electro-deposition method, a hybrid process, a hybrid sputtering RR method, a nanoparticle printing method, a nanoparticle printing RR method, or the FASST (registered trademark) process).

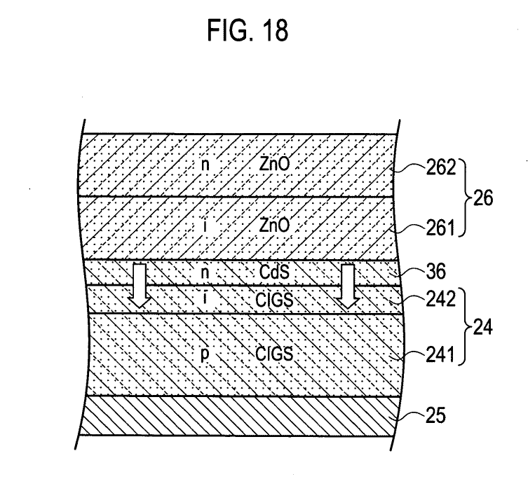

FIG. 18 is a schematic cross-sectional structure diagram of a photoelectric conversion unit in the photoelectric converter formed by the process for producing the photoelectric converter according to the first embodiment of the present invention. The process for producing the photoelectric converter according to the first embodiment makes it possible to easily form the i-type CIGS layer 242 on the surface of the compound semiconductor thin film 24 with good control of the film thickness while reducing the Cu/group III (In+Ca) ratio in the third step of the three-step method described above. Also, the i-type CIGS layer 242 can be easily formed to have a small thickness.

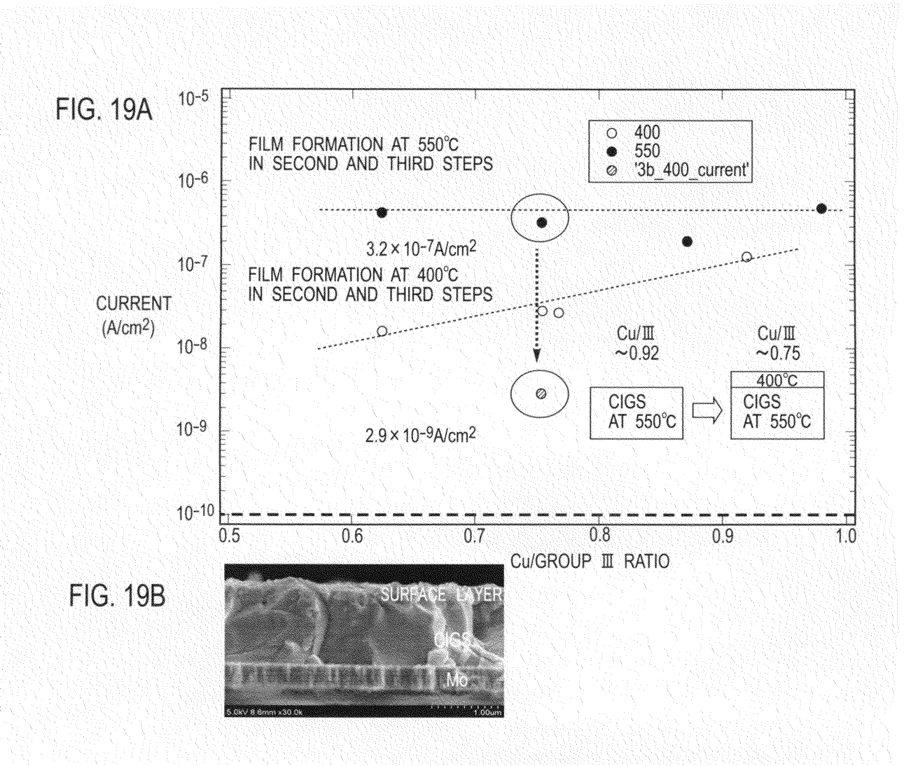

FIG. 19A shows a relationship between dark current density (A/cm²) and the Cu/group III ratio as a result of applying the process for producing the photoelectric converter to a test structure, and FIG. 19B shows an SEM photograph of an example of the test structure having Mo and CIGS stacked on a substrate.

For example, when the substrate temperature is set to about 550° C. in both of the second and third steps as in FIG. 15A, the dark current value is about 3.2×10⁻⁷ (A/cm²), and no significant dependence is observed even when the Cu/group III ratio is changed.

For example, when the substrate temperature is set to about 400° C. in both of the second and third steps as in FIG. 15A, the dark current value is about 1.5×10⁻⁸ (A/cm²) to 1×10⁻⁷ (A/cm²). The dark current value tends to be gradually increased as the Cu/group III ratio is increased to about 0.6 to about 0.92.

In contrast, when the substrate temperature is set to about 550° C. in both of the second step and the period 3a of the third step while shifting the Cu/group III ratio to a value of 1.0 or less, and is set to about 400° C. in the period 3b of the third step as in FIG. 17A while shifting the Cu/group III ratio to a further smaller value, the dark current value is about 2.9×10⁻⁹ (A/cm²), and significant reduction dependence is observed.

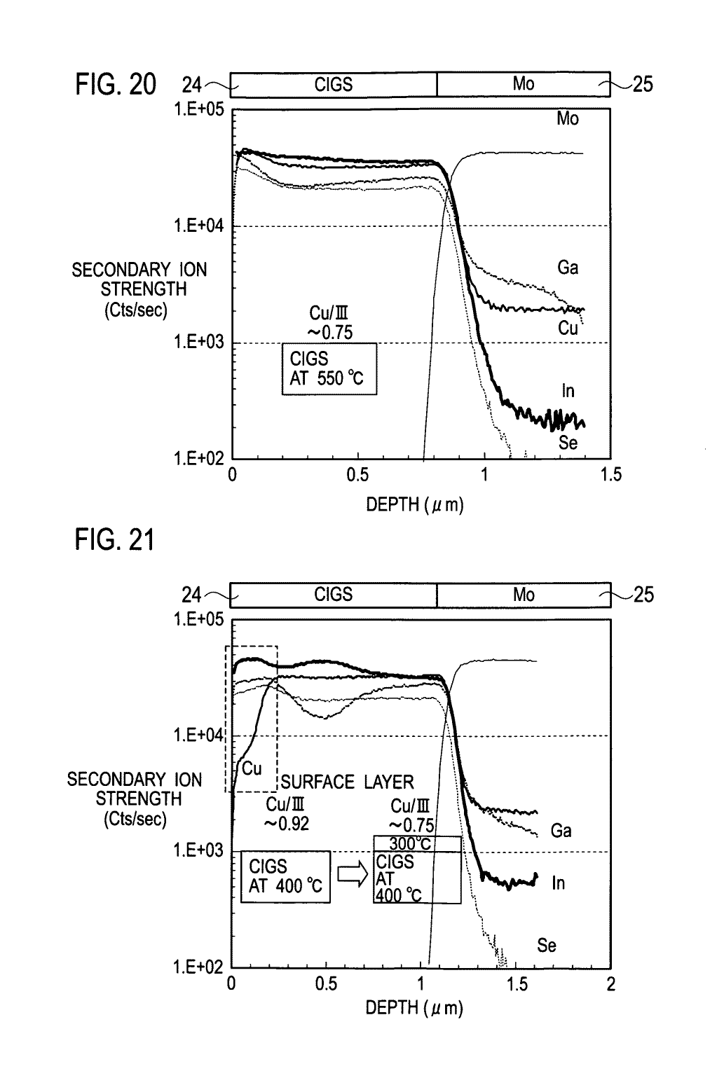

FIG. 20 shows an analysis result obtained by SIMS on the photoelectric conversion unit formed by the process for producing the photoelectric converter according to the comparative example of the present invention. Here, the substrate temperature is set to about 550° C. in both of the second and third steps, and the Cu/group III ratio is about 0.75. In the SIMS analysis result shown in FIG. 20, reduction in Cu element is not observed in the surface of the compound semiconductor thin film 24. That is, the surface layer of the compound semiconductor thin film 24 is not formed into the i-type.

In contrast, FIG. 21 shows an analysis result obtained by SIMS on the photoelectric conversion unit formed by the process for producing the photoelectric converter according to the first embodiment of the present invention. When the substrate temperature is set to about 400° C. in both of the second step and the period 3a of the third step, and is set to about 300° C. in the period 3b of the third step, significant reduction in Cu element in the surface of the compound semiconductor thin film 24 is observed in the state where the Cu/group III ratio is 0.75. That is, the surface layer of the compound semiconductor thin film 24 is formed into the i-type, and thus the i-type CIGS layer 242 is formed. Here, the substrate temperature is set to about 400° C. in the second step, and the Cu/group III ratio is set to 0.92. In addition, the substrate temperature is set to about 300° C. in the period 3b of the third step, and the Cu/group III ratio is set to 0.7. As is clear from FIG. 21, the thickness of the surface layer (i-type CIGS layer 242) of the compound semiconductor thin film 24 formed into the i-type is about 200 nm.

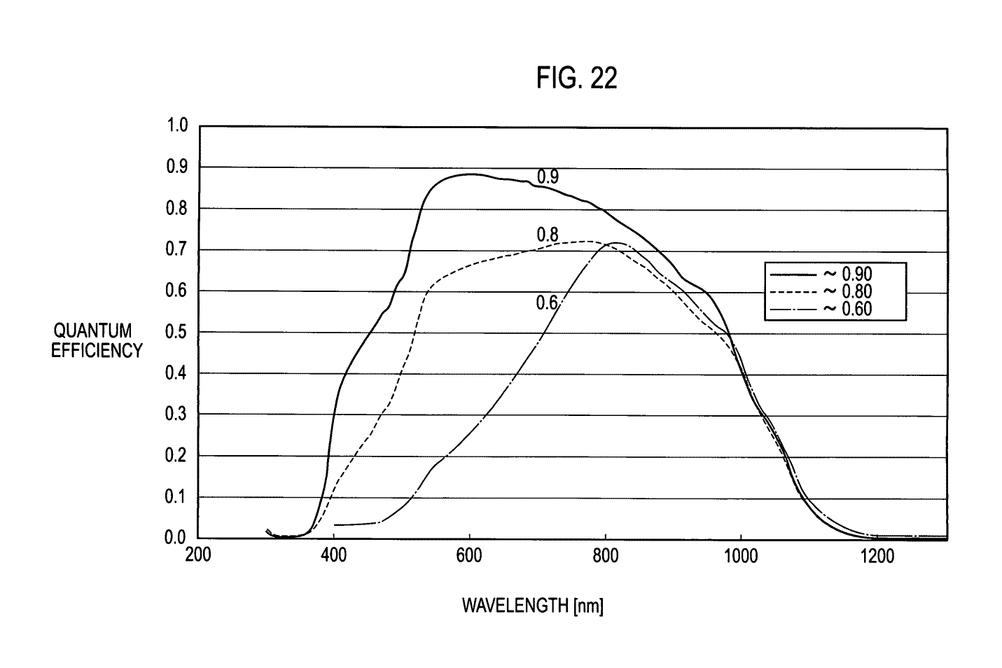

FIG. 22 shows a wavelength characteristic of quantum efficiency using, as a parameter, the value of Cu/group III ratio of the compound semiconductor thin film (CIGS thin film) formed by the process for producing the photoelectric converter according to the first embodiment of the present invention. Here, as for the formation condition of the compound semiconductor thin film (CIGS thin film) 24, as in the case of FIG. 21, the substrate temperature is set to about 400° C. in both of the second step and the period 3a of the third step, and is set to about 300° C. in the period 3b of the third step.

As is clear from FIG. 22, the quantum efficiency tends to be reduced as the value of Cu/group III ratio of the compound semiconductor thin film 24 is reduced to 0.9, to 0.8, and then to 0.6. To put it simply, the reduction in value of Cu/group III ratio of the compound semiconductor thin film 24 to 0.9, to 0.8, and then to 0.6 corresponds to the reduction in the Cu fraction by extending the period 3b. This is because the thickness of the surface layer (i-type CIGS layer 242) of the compound semiconductor thin film 24 formed into the i-type is increased and the quantum efficiency at the short wavelength side is reduced.

(Photoelectric Conversion Characteristics)

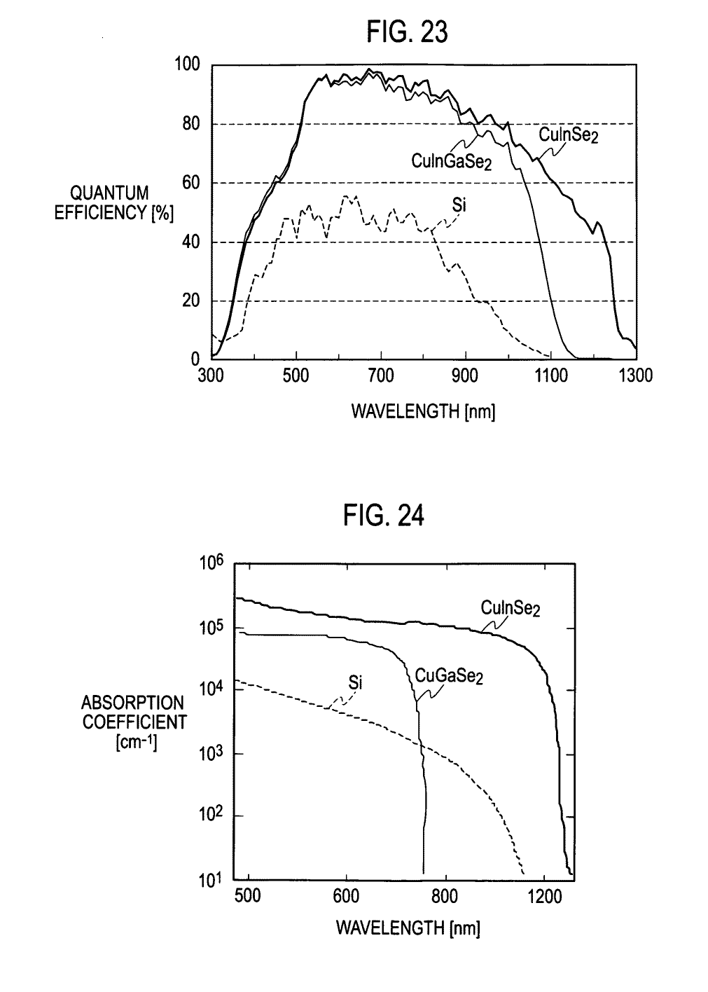

FIG. 23 shows wavelength characteristics of the quantum efficiency of the photoelectric converter according to the first embodiment. Specifically, FIG. 23 shows the photoelectric conversion characteristics of high quantum efficiency in the wide wavelength region from visible light to near infrared light, reflecting the quantum efficiency of the compound semiconductor thin film (Cu(In_{X}, Ga_{1-X})Se₂ (0≦X≦1)) 24 of chalcopyrite structure which functions as the light absorbing layer. The quantum efficiency is more than doubled compared with the photoelectric conversion characteristics in the case of silicon (Si).

The wavelength region can be extended to about 1300 nm which is a wavelength of the near infrared light by changing the composition of the compound semiconductor thin film (Cu(In_{X}, Ga_{1-X})Se₂ (0≦X≦1)) 24 of chalcopyrite structure which functions as the light absorbing layer from Cu(InGa)Se₂ to Cu(In)Se₂.

(Optical Absorption Characteristics)

FIG. 24 shows optical absorption characteristics of the photoelectric converter according to the first embodiment. Specifically, the photoelectric converter has strong absorption performance in the wide wavelength region from visible light to near infrared light, reflecting optical absorption coefficient characteristics of the compound semiconductor thin film (Cu(In_{X}, Ga_{1-X})Se₂ (0≦X≦1)) 24 of chalcopyrite structure which functions as the light absorbing layer.

For example, the absorption coefficient is about 100 times that of silicon (Si) also in the visible light wavelength region, and the absorption performance can be extended to the wavelength of about 1300 nm by changing the composition of the compound semiconductor thin film (Cu(In_{X}, Ga_{1-X})Se₂ (0≦X≦1)) 24 of chalcopyrite structure which functions as the light absorbing layer from CuGaSe₂ to CuInSe₂.

(Band Gap Energy and In/(In+Ga) Composition Ratio Characteristics)

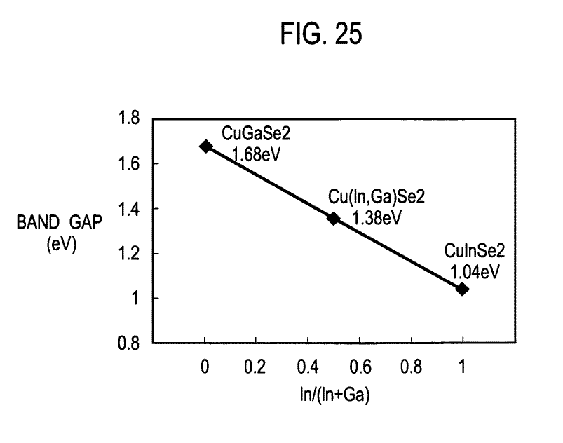

FIG. 25 shows the dependence of In/(In+Ga) composition ratio and the band gap energy of the compound semiconductor thin film (Cu(In_{X}, Ga_{1-X})Se₂ (0≦X≦1)) of chalcopyrite structure which is applied to the photoelectric converter according to the first embodiment.

As shown in FIG. 25, the band gap energy of Cu(Ga)Se₂ is 1.68 eV, the band gap energy of Cu(In, Ga)Se₂ is 1.38 eV, and the band gap energy of Cu(In)Se₂ is 1.04 eV.

The band gap energy of the compound semiconductor thin film (Cu(In_{X}, Ga_{1-X})Se₂ (0≦X≦1)) of chalcopyrite structure can be made variable by controlling the In/(In+Ga) composition ratio as shown in FIG. 25. Thus, the photoelectric conversion wavelength can also be made variable by composition control. For example, for dark current reduction, the band gap energy may be increased by making Ga excessive near the top and bottom surfaces of the CIGS film. Moreover, for example, in order to improve the photoelectric conversion efficiency in the near-infrared wavelength region, the band gap energy may be reduced by making In excessive in the range of a predetermined depth in the CIGS film.

Moreover, in formation of the CIGS surface layer described above with reference to FIGS. 17A and 17B, if the Ga component is increased while setting the Cu/group III ratio constant during the surface layer formation, the band gap energy is increased at the surface side and thus the quantum efficiency at the short wavelength side can be improved.

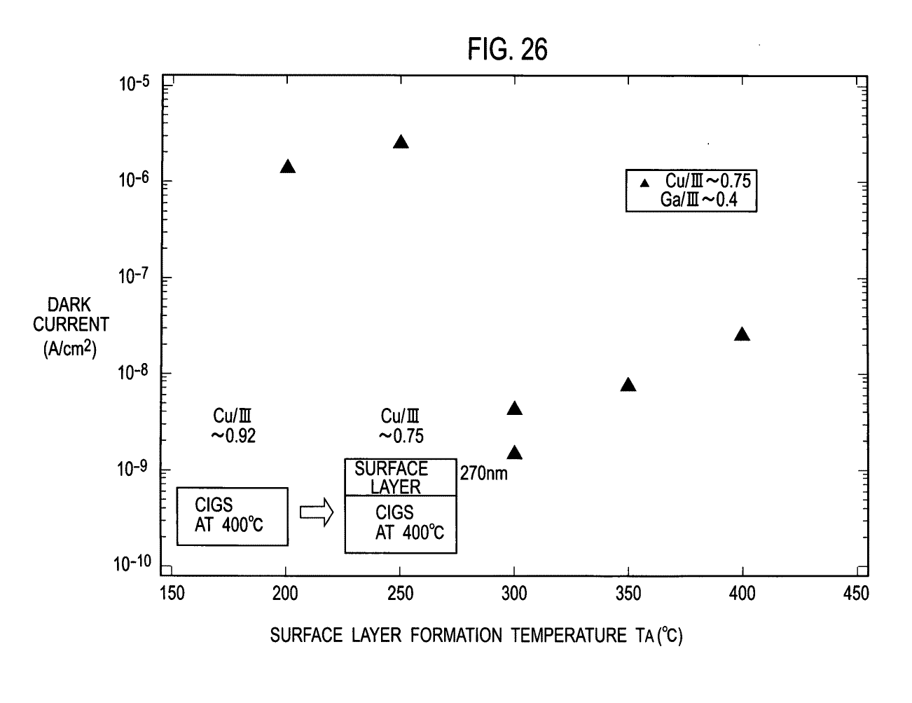

FIG. 26 shows the relationship between the dark current (A/cm²) and the surface layer formation temperature T_{A} (° C.) in the photoelectric converter produced by the process for producing the photoelectric converter according to the first embodiment of the present invention. The dark current characteristics are improved by forming the surface layer (i-type CIGS layer 242) while setting the surface layer formation temperature T_{A} to about 300° C. to 400° C., for example, after the p-type CIGS layer 241 is formed. Even if the surface layer formation temperature T_{A} is lowered, for example, from about 400° C. to about 300° C., the dark current characteristics are improved. On the other hand, when the surface layer formation temperature T_{A} is set to, for example, about 300° C. or lower, the dark current value is increased and the dark current characteristics are deteriorated.

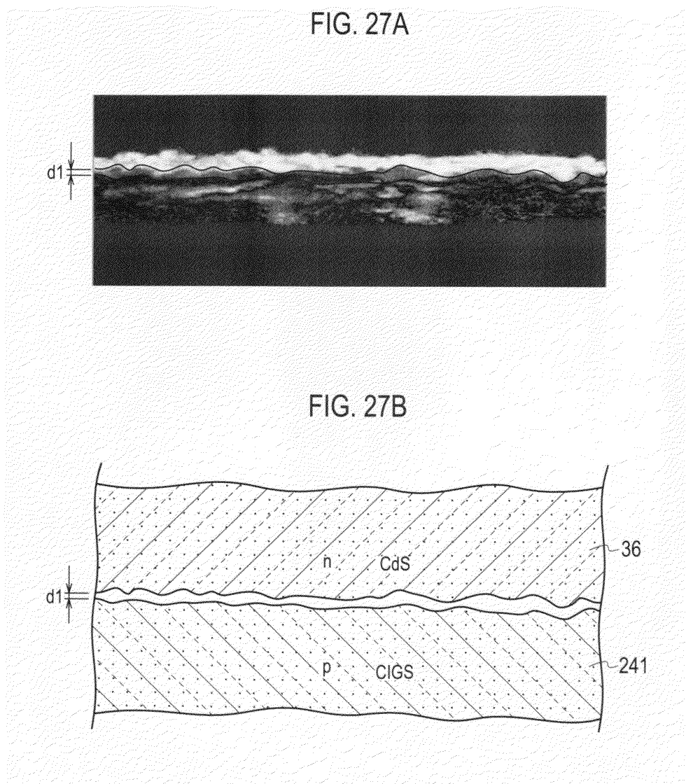

FIG. 27A shows an example of SCM (Scanning Capacitance Microscope) photograph of the photoelectric conversion unit of the photoelectric converter produced by the process for producing the photoelectric converter according to the comparative example of the first embodiment. Also, FIG. 27B is an explanatory diagram of FIG. 27A. As in the case of FIG. 16, a pn junction formed of the p-type CIGS layer 241 and the n-type buffer layer (CdS) 36 is formed in the photoelectric conversion unit of the photoelectric converter according to the comparative example.

The region in which no dC/dV signal is outputted in the boundary of the p-type CIGS layer 241 and the n-type buffer layer (CdS) 36 indicates a junction depletion layer having a width d1. In the comparative example, a region which becomes n-type over a large area is observed in the p-type CIGS layer 241 (not shown in FIG. 27B). Such a region is considered to contribute to a leak path accompanied by the increase in dark current.

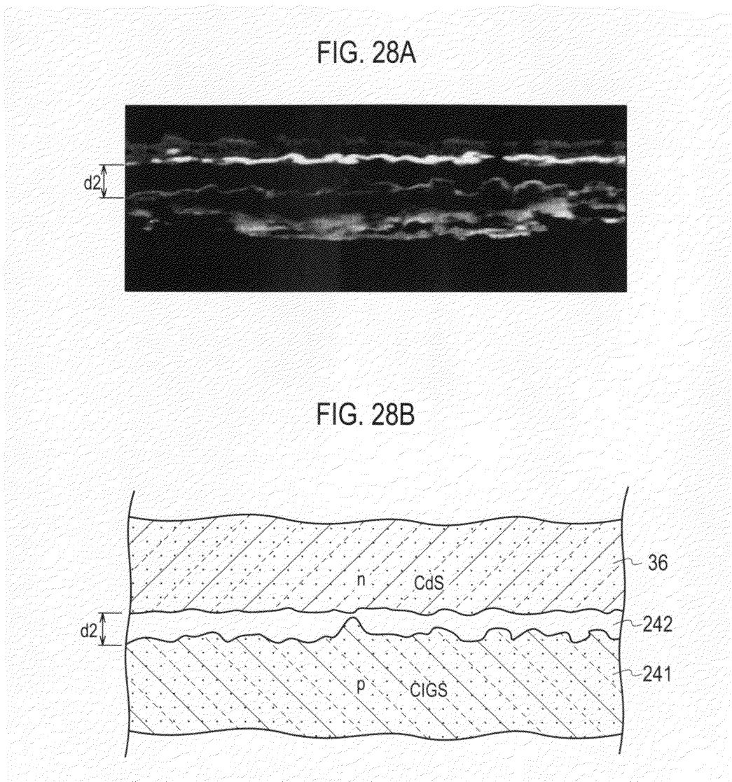

FIG. 28A shows an example of SCM photograph of the photoelectric conversion unit of the photoelectric converter produced by the process for producing the photoelectric converter according to the first embodiment. Also, FIG. 28B is an explanatory diagram of FIG. 28A. As in the case of FIG. 18, a pin junction formed of the p-type CIGS layer 241, the i-type CIGS layer 242 and the n-type buffer layer (CdS) 36 is formed in the photoelectric conversion unit of the photoelectric converter according to the first embodiment.

A region in which no dC/dV signal is outputted in the boundary of the p-type CIGS layer 241 and the n-type buffer layer (CdS) 36 indicates a junction depletion layer having a width d2. In the first embodiment, regions reversed to the n-type are hardly observed in the p-type CIGS layer 241. Therefore, it is considered that the leak path accompanied by the increase in dark current does not exist, which contributes to improvement in dark current characteristics.

(Solid State Imaging Device)

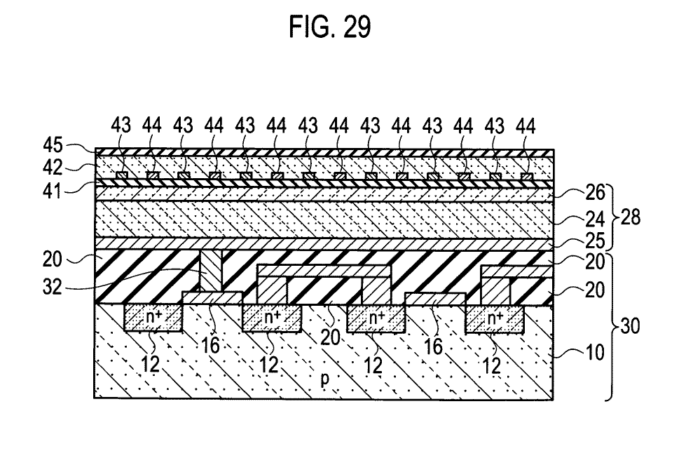

A solid state imaging device configured by applying the photoelectric converter according to the first embodiment of the present invention includes a circuit portion 30 formed on a semiconductor substrate 10, and a photoelectric conversion unit 28 disposed on the circuit portion 30, as shown in FIG. 29 as a cross-sectional diagram of one pixel part. Note that FIG. 29 omits illustration of a buffer layer 36.

The solid state imaging device shown in FIG. 29 includes: the circuit portion 30 formed on the semiconductor substrate 10; a lower electrode layer 25 disposed on the circuit portion 30 and mutually separated between pixels adjacent to each other in a column direction or in a row direction; a compound semiconductor thin film 24 of chalcopyrite structure disposed on the lower electrode layer 25 and mutually separated between the pixels adjacent to each other in the column direction or in the row direction; a buffer layer 36 disposed on the compound semiconductor thin film 24; and a transparent electrode layer 26 disposed on the buffer layer 36. Here, the column direction is a direction in which a bit line to read a signal of each pixel is extended, while the row direction is a direction orthogonal to the column direction, in which a word line that is an address line to each pixel is extended.

The lower electrode layer 25, the compound semiconductor thin film 24, the buffer layer 36 and the transparent electrode layer 26 are sequentially stacked on the circuit portion 30.

Moreover, a reverse bias voltage is applied between the transparent electrode layer 26 and the lower electrode layer 25 to cause impact ionization in the compound semiconductor thin film 24 with the chalcopyrite structure, so that the multiplication of charges generated by photoelectric conversion is induced.

The circuit portion 30 includes a transistor having a gate connected to the lower electrode layer 25.

The circuit portion 30 may be integrated with the lower electrode layer 25, the compound semiconductor thin film 24, the buffer layer 36 and the transparent electrode layer 26, which are sequentially stacked on the circuit portion 30.

Moreover, in the solid state imaging device shown in FIG. 29, the compound semiconductor thin film 24 of chalcopyrite structure is formed of (Cu(In_{X}, Ga_{1-X})Se₂ (0≦X≦1)).

As the lower electrode layer 25, molybdenum (Mo), niobium (Nb), tantalum (Ta), tungsten (W) or the like can be used, for example.

As a material to form the buffer layer 36, CdS, ZnS, ZnO, ZnMgO, ZnSe, In₂S₃ or the like can be used, for example.

The solid state imaging device shown in FIG. 29 can also be configured as an image sensor having sensitivity also in a near infrared light region.

The solid state imaging device shown in FIG. 29 may include a color filter on the transparent electrode layer 26. Three color filters for red, green and blue may be provided as one unit in adjacent respective pixels 5. Alternatively, four color filters, by adding a filter for near infrared light, may be set as one unit. These four filters may be arranged in a matrix pattern of 2×2. The color filters can be formed by multilayering gelatin films, for example. Moreover, an ultraviolet protection filter for cutting off ultraviolet light having a wavelength around 400 nm can also be used. The ultraviolet protection filter can be formed to have a structure in which inorganic materials having different refractive indices are alternately stacked in multiple cycles. For example, a TiO₂ film and a SiO₂ film may be selected as dielectric films having different refractive indices, and these films may be alternately stacked in multiple cycles.

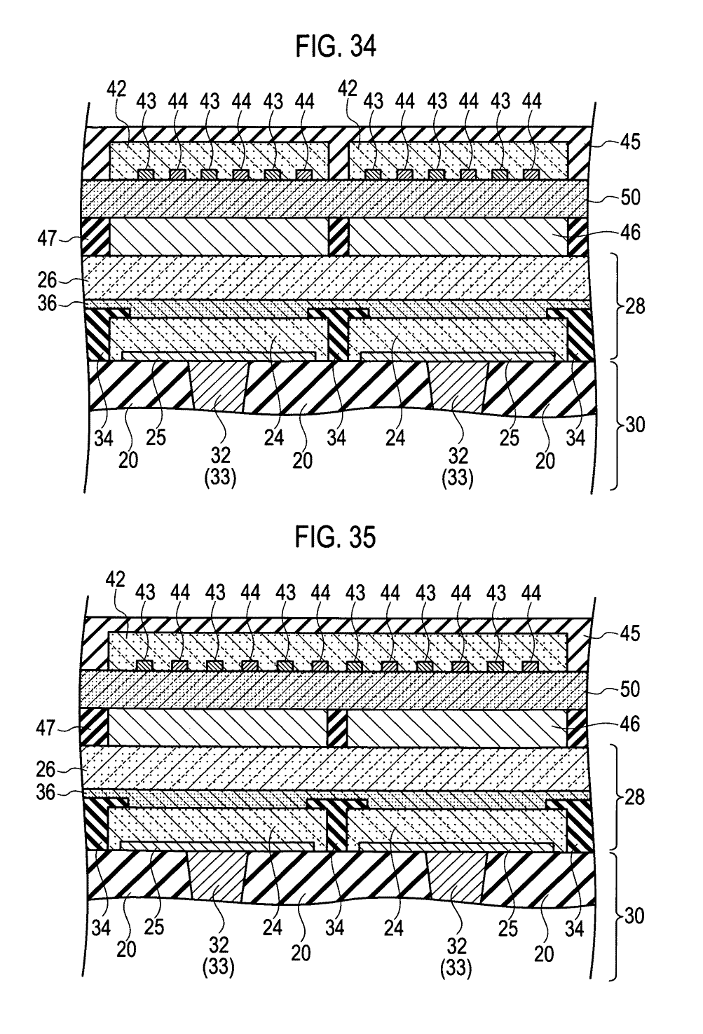

FIGS. 34 and 35 show examples where the filters described above are formed. FIG. 34 shows an example where a color filter 46 is provided in the structure shown in FIG. 3, while FIG. 35 shows an example where the color filter 46 is provided in the structure shown in FIG. 4. In either case, the ZnO-based compound semiconductor thin film 42 is formed on the substrate 50, instead of the interlayer insulating film 41. Reference numeral 47 denotes an insulating film.

In the solid state imaging device shown in FIG. 29, the photoelectric conversion unit 28 and the gate electrode 16 of the n-channel MOS transistor which constitutes a part of the CMOS are electrically connected to each other by the VIA electrode 32 disposed on the gate electrode 16.

Since an anode of a photodiode which constitutes the photoelectric conversion unit 28 is connected to the gate electrode 16 of the n-channel MOS transistor, optical information detected in the photodiode is amplified by the n-channel MOS transistor.

Also, the configuration having the buffer layer 36 has been described above as an embodiment. Although the leakage current can be reduced by the buffer layer 36, the present invention is not limited thereto. The present invention is applicable to a configuration in which an electrode layer is provided, without the buffer layer, on the compound semiconductor thin film (CIGS) layer.

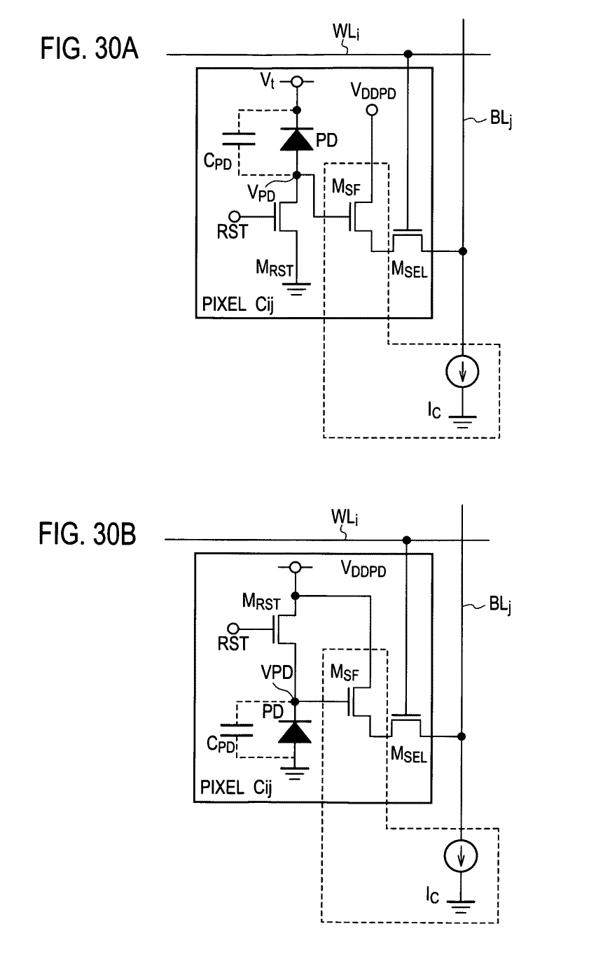

FIG. 30A shows a circuit configuration of one pixel Cᵢⱼ of the solid state imaging device configured by applying the photoelectric converter according to the first embodiment. As shown in FIG. 30A, the circuit configuration includes a photodiode PD and three MOS transistors, for example. On the other hand, FIG. 30B shows a circuit configuration of one pixel Cᵢⱼ of the solid state imaging device according to the comparative example of the present invention, for example. Since a high reverse bias voltage is applied between the anode and cathode of the photodiode PD in the solid state imaging device configured by applying the photoelectric converter according to the first embodiment, it is necessary to adopt a circuit configuration different from the circuit configuration of one pixel Cᵢⱼ of the solid state imaging device according to the comparative example in which a relatively low voltage is applied.

Moreover, as for the solid state imaging device configured by applying the photoelectric converter according to the first embodiment, photoelectric conversion cells each including the circuit portion 30 and the photoelectric conversion unit 28 are integrated in a one-dimensional or two-dimensional matrix pattern.

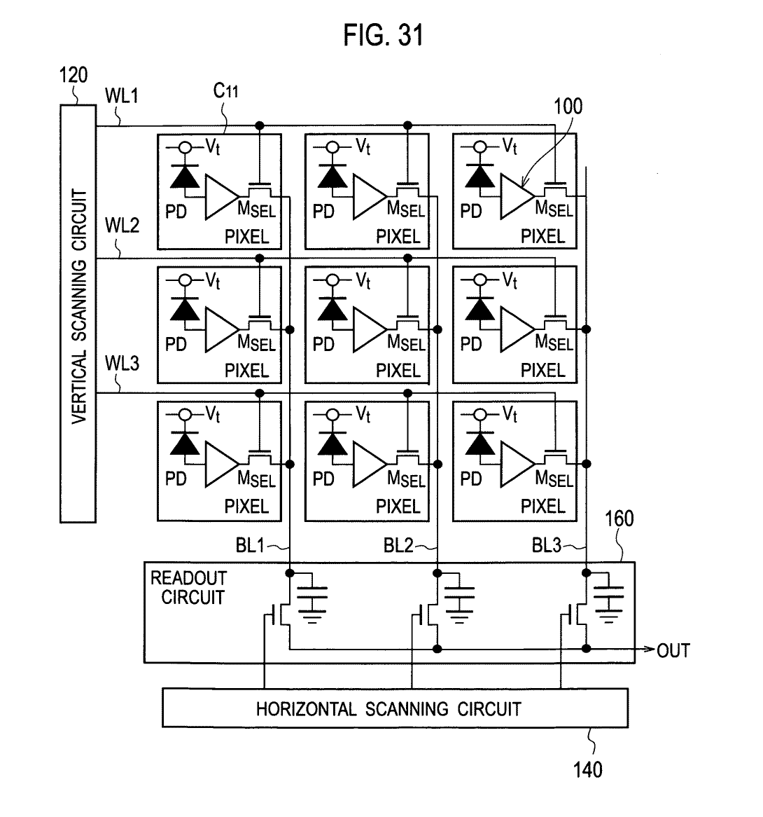

As shown in FIG. 31, the solid state imaging device configured by applying the photoelectric converter according to the first embodiment includes: multiple word lines WLᵢ (where i=1 to m, and m is an integer) disposed in the row direction; multiple bit lines BLⱼ (where j=1 to n, and n is an integer) disposed in the column direction; pixels Cᵢⱼ disposed at the intersections between the word lines WLᵢ and the bit lines BLⱼ; a vertical scanning circuit 120 connected to the multiple word lines WLᵢ; a readout circuit 160 connected to the multiple bit lines BLⱼ; and a horizontal scanning circuit 140 connected to the readout circuit 160. Note that the configuration is shown in the 3×3 matrix pattern in the configuration example of FIG. 31, but can be extended to the matrix of m×n as described above.

The circuit configuration of each pixel shown in FIG. 31 corresponds to that shown in FIG. 30A. A buffer 100 is a source follower surrounded by the broken line in FIG. 30A, and includes a constant current source Ic and a MOS transistor M_{SF}. A selection MOS transistor M_{SEL} has a gate connected to the word line WL. A target voltage Vₜ (V) is applied to the cathode of the photodiode PD. A capacitor C_{PD} is a depletion layer capacitance of the photodiode PD, and is a capacitor configured to accumulate charges.

The MOS transistor M_{SF} of the source follower has a drain connected to a power supply voltage V_{DDPD}. The anode of the photodiode PD is connected to a reset MOS transistor M_{RST}, and the photodiode PD is reset to its initial state when a signal is inputted to a reset terminal RST.

Note that although the circuit portion 30 has been described as a semiconductor integrated circuit disposed on the semiconductor substrate 10 in the example of FIG. 29, the circuit portion 30 can also be formed using a thin film transistor integrated circuit in which thin film transistors formed on a thin film formed on a glass substrate are integrated, for example.

As is clear from FIG. 3, in the solid state imaging device shown in FIG. 29, the compound semiconductor thin film 24 disposed on the lower electrode layer 25 is separated mutually by an element isolation region 34 between adjacent pixel cells.

Moreover, the buffer layer 36 disposed on the compound semiconductor thin film 24 and the element isolation region 34 is formed integrally all over the semiconductor substrate surface.

FIG. 29 omits illustration of a gate insulating film disposed on the semiconductor substrate 10 between source/drain regions 12. Moreover, a VIA electrode 32 buried in an interlayer insulating film 20 is disposed between the gate electrode 16 and the lower electrode layer 25.

Moreover, in multiple integrated pixels, the transparent electrode layer 26 is integrally formed on the semiconductor substrate surface, and is made electrically common.

That is, the transparent electrode layer 26 becomes a cathode electrode of the photodiode (PD) which constitutes the photoelectric conversion unit 28, and is set to have a constant potential (target voltage Vₜ) for applying a high electric field. Therefore, in the multiple integrated pixels, the cathode electrode of the photodiode (PD) which constitutes the photoelectric conversion unit 28 does not need to be separately formed, but is integrally formed on the semiconductor substrate surface and is made electrically common.

The stacked structure of the circuit portion 30 and the photoelectric conversion unit 28 enables the whole pixel region of the photoelectric conversion cell to be used as a substantial photoelectric conversion region. Accordingly, in a CMOS type image sensor, an aperture ratio is about 80% to 90% compared with an aperture ratio of about 30% to 40% in the case where the photoelectric conversion unit 28 is formed as a pn junction diode in the semiconductor substrate, thus achieving a considerable improvement effect.

Note that the transparent electrode layer (ZnO film) 26 becomes equipotential, and thus does not need to be separately formed for each pixel. However, in the case of a large-capacity area sensor or the like with which resistivity becomes a problem, electrodes each made of aluminum or the like may be disposed in a mesh or stripe pattern on the transparent electrode layer 26 at a fixed pitch to such extent that the aperture ratio of the pixel is not affected.

The first embodiment can provide a photoelectric converter and a process for producing the same, which achieve a high S/N ratio by applying a high electric field to the photoelectric conversion unit using the chalcopyrite semiconductor to cause the multiplication of charges by impact ionization and by improving dark current characteristics to considerably improve detection efficiency even at low luminance.

The first embodiment can provide a photoelectric converter and a process for producing the same, in which improvement in dark current characteristics leads to observation of a multiplication phenomenon that has never heretofore been observed, thus enabling even low luminance light to be detected.

The first embodiment can provide a solid state imaging device which achieves a high S/N ratio by applying a high electric field to the photoelectric conversion unit using the chalcopyrite semiconductor to cause the multiplication of charges by impact ionization, and by improving dark current characteristics to considerably improve detection efficiency even at low luminance.

The first embodiment can provide a solid state imaging device in which improvement in dark current characteristics leads to observation of a multiplication phenomenon that has never heretofore been observed, thus enabling even low luminance light to be detected.

### Second Embodiment

(Plane Pattern Configuration)

A whole schematic plane pattern configuration of a solid state imaging device configured by two-dimensionally arranging photoelectric converters according to a second embodiment of the present invention is the same as that shown in FIG. 1. Therefore, description thereof is omitted.

(Photoelectric Converter)

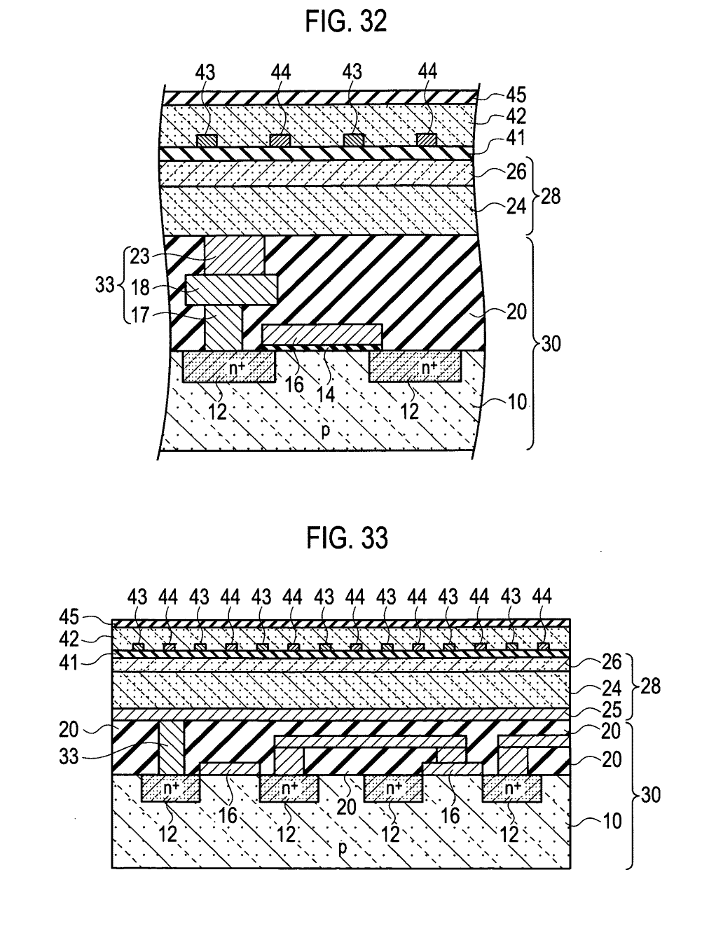

FIG. 32 shows a schematic cross-sectional structure of the photoelectric converter according to the second embodiment. As shown in FIG. 32, the photoelectric converter includes: a circuit portion 30 formed on a substrate; and a photoelectric conversion unit 28 disposed on the circuit portion 30. Note that FIG. 32 omits illustration of a lower electrode layer 25 and a buffer layer 36.

The photoelectric converter shown in FIG. 32 includes: the circuit portion 30 formed on a semiconductor substrate 10; the lower electrode layer 25 disposed on the circuit portion 30; a compound semiconductor thin film 24 of chalcopyrite structure disposed on the lower electrode layer 25; the buffer layer 36 disposed on the compound semiconductor thin film 24; and the transparent electrode layer 26 disposed on the buffer layer 36.

The lower electrode layer 25, the compound semiconductor thin film 24, the buffer layer 36 and the transparent electrode layer 26 are sequentially stacked on the circuit portion 30.

In the photoelectric converter according to the second embodiment, a reverse bias voltage is applied between the transparent electrode layer 26 and the lower electrode layer 25 to cause impact ionization in the compound semiconductor thin film 24 of chalcopyrite structure, so that the multiplication of charges generated by photoelectric conversion is induced.

The circuit portion 30 includes a transistor having a source or a drain connected to the lower electrode layer 25.

The circuit portion 30 may be integrated with the lower electrode layer 25, the compound semiconductor thin film 24, the buffer layer 36 and the transparent electrode layer 26, which are sequentially stacked on the circuit portion 30.

In the photoelectric converter shown in FIG. 32, the compound semiconductor thin film 24 of chalcopyrite structure is formed of Cu(In_{X}, Ga_{1-X})Se₂(0≦X≦1).

As the lower electrode layer 25, molybdenum (Mo), niobium (Nb), tantalum (Ta), tungsten (W), or the like can be used, for example.

As a material to form the buffer layer 36, CdS, ZnS, ZnO, ZnMgO, ZnSe, In₂S₃ or the like can be used, for example.

The transparent electrode layer 26 is formed of a non-doped ZnO film (i-ZnO) disposed on the compound semiconductor thin film 24, and an n-type ZnO film disposed on the non-doped ZnO film (i-ZnO).

The photoelectric converter shown in FIG. 32 can also be configured as a photosensor having sensitivity also in a near infrared light region.

The compound semiconductor thin film 24 includes a high-resistivity layer (i-type CIGS layer) on its surface.

FIG. 32 shows an n-channel MOS transistor which constitutes a part of a CMOS in the circuit portion 30. The circuit portion 30 includes: the semiconductor substrate 10; source/drain regions 12 formed in the semiconductor substrate 10; a gate insulating film 14 disposed on the semiconductor substrate 10 between the source/drain regions 12; a gate electrode 16 disposed on the gate insulating film 14; a VIA0 electrode 17 disposed on one of the source/drain regions 12; a wiring layer 18 for the source/drain disposed on the VIA0 electrode 17; and a VIA1 electrode 23 disposed on the wiring layer 18.

The gate electrode 16, the VIA0 electrode 17, the wiring layer 18, and the VIA1 electrode 23 are all formed in an interlayer insulating film 20.

A VIA electrode 33 disposed on the source/drain region 12 is formed of the VIA0 electrode 17, the wiring layer 18 disposed on the VIA0 electrode 17, and the VIA1 electrode 23 disposed on the wiring layer 18.

In the photoelectric converter shown in FIG. 32, the photoelectric conversion unit 28 and the source/drain region 12 of the n-channel MOS transistor which constitutes a part of the CMOS are electrically connected to each other by the VIA electrode 33 disposed on the source/drain region 12.

In the photoelectric converter shown in FIG. 32, reflecting the difference in the circuit configuration, the photoelectric converter itself has no amplifying function compared with that in the first embodiment.

As in FIG. 3, FIG. 32 shows a more detailed cross-sectional structure including adjacent pixels of the solid state imaging device formed by two-dimensionally arranging the photoelectric converters according to the second embodiment. FIG. 32 corresponds to a case where the solid state imaging device includes the VIA electrode 33 instead of the VIA electrode 32 in FIG. 3.

As is clear from FIG. 3, the lower electrode layer 25 and the compound semiconductor thin film 24 disposed on the lower electrode layer 25 in a pixel cell are separated from those in another pixel cell adjacent thereto by an element isolation region 34 formed of an interlayer insulating film. Moreover, the buffer layer 36 disposed on the compound semiconductor thin film 24 is integrally formed all over the semiconductor substrate surface. Also, the transparent electrode layer 26 is integrally formed all over the semiconductor substrate surface, and is made electrically common.

Note that the compound semiconductor thin film 24 and the lower electrode layer 25 may have the same width, or more specifically, as shown in FIG. 3, the compound semiconductor thin film 24 may be set to have a larger width than the lower electrode layer 25.

The configuration described above can prevent leakage while filling a void or a pinhole generated in an underlying CIGS thin film with a semi-insulating layer by providing a non-doped ZnO film (i-ZnO) as the transparent electrode layer 26. Therefore, the dark current on the pn junction interface can be reduced by increasing the thickness of the non-doped ZnO film (i-ZnO).

Since the anode of the photodiode which constitutes the photoelectric conversion unit 28 is connected to the source/drain region 12 of the n-channel MOS transistor, the optical information detected in the photodiode is switched by the n-channel MOS transistor.

Note that the circuit portion 30 can also be formed using a thin film transistor having a CMOS configuration formed on a thin film formed on a glass substrate, for example.

Also in the photoelectric converter according to the second embodiment, since the configuration of the photoelectric conversion unit 28 is the same as that of the photoelectric converter according to the first embodiment, both of the multiplication mechanism of the photoelectric conversion unit 28 shown in FIGS. 11A and 11B to FIG. 14, the production process of the photoelectric converter shown in FIGS. 17A and 17B, etc. are the same as those of the photoelectric converter according to the first embodiment. Therefore, description thereof is omitted.

Also, the configuration having the buffer layer 36 has been described above as an embodiment. Although the leakage current can be reduced by the buffer layer 36, the present invention is not limited thereto. The present invention is applicable to a configuration in which an electrode layer is provided, without the buffer layer, on the compound semiconductor thin film (CIGS) layer.

(Solid State Imaging Device)

A solid state imaging device configured by applying the photoelectric converter according to the second embodiment of the present invention includes a circuit portion 30 formed on a semiconductor substrate 10, and a photoelectric conversion unit 28 disposed on the circuit portion 30, as shown in FIG. 33 as a cross-sectional diagram of one pixel part. Note that FIG. 33 omits illustration of a buffer layer 36.

The solid state imaging device shown in FIG. 33 includes: the circuit portion 30 formed on the semiconductor substrate 10; a lower electrode layer 25 disposed on the circuit portion 30 and mutually separated between pixels adjacent to each other in a column direction or in a row direction; a compound semiconductor thin film 24 of chalcopyrite structure disposed on the lower electrode layer 25 and mutually separated between the pixels adjacent to each other in the column direction or in the row direction; a buffer layer 36 disposed on the compound semiconductor thin film 24; and a transparent electrode layer 26 disposed on the buffer layer 36 and having a planarized structure over the adjacent pixels. Here, the column direction is a direction in which a bit line to read a signal of each pixel is extended, while the row direction is a direction orthogonal to the column direction, in which a word line that is an address line to each pixel is extended.

The lower electrode layer 25, the compound semiconductor thin film 24, the buffer layer 36 and the transparent electrode layer 26 are sequentially stacked on the circuit portion 30.

A reverse bias voltage is applied between the transparent electrode layer 26 and the lower electrode layer 25 to cause impact ionization in the compound semiconductor thin film 24 with the chalcopyrite structure, so that the multiplication of charges generated by photoelectric conversion is induced.

The circuit portion 30 includes a transistor having a source or a drain connected to the lower electrode layer 25.

The circuit portion 30 may be integrated with the lower electrode layer 25, the compound semiconductor thin film 24, the buffer layer 36 and the transparent electrode layer 26, which are sequentially stacked on the circuit portion 30.

Moreover, in the solid state imaging device shown in FIG. 33, the compound semiconductor thin film 24 of chalcopyrite structure is formed of (Cu(In_{X}, Ga_{1-X})Se₂ (0≦X≦1)).

As the lower electrode layer 25, molybdenum (Mo), niobium (Nb), tantalum (Ta), tungsten (W) or the like can be used, for example.

As a material to form the buffer layer 36, CdS, ZnS, ZnO, ZnMgO, ZnSe, In₂S₃ or the like can be used, for example.

The solid state imaging device shown in FIG. 33 can also be configured as an image sensor having sensitivity also in a near infrared light region.

The solid state imaging device shown in FIG. 33 may include a color filter on the transparent electrode layer 26. Three color filters for red, green and blue may be provided as one unit in adjacent respective pixels 5. Alternatively, four color filters, by adding a filter for near infrared light, may be set as one unit. These four filters may be arranged in a matrix pattern of 2×2. The color filters can be formed by multilayering gelatin films, for example.

In the solid state imaging device shown in FIG. 33, the photoelectric conversion unit 28 and the source/drain region 12 of the n-channel MOS transistor which constitutes a part of the CMOS are electrically connected to each other by the VIA electrode 33 disposed on the source/drain region 12.

Since an anode of a photodiode which constitutes the photoelectric conversion unit 28 is connected to the source/drain region 12 of the n-channel MOS transistor, optical information detected in the photodiode is switched by the n-channel MOS transistor.

A circuit configuration of one pixel Cᵢⱼ of the solid state imaging device configured by applying the photoelectric converter according to the second embodiment is different from that of FIG. 30A, but configuration includes a photodiode PD and three MOS transistors, for example (not shown). Since a high reverse bias voltage is applied between the anode and cathode of the photodiode PD also in the solid state imaging device configured by applying the photoelectric converter according to the second embodiment, it is necessary to adopt a circuit configuration different from the circuit configuration of one pixel Cᵢⱼ of the solid state imaging device according to the comparative example in which a relatively low voltage is applied.

Moreover, as for the solid state imaging device configured by applying the photoelectric converter according to the second embodiment, photoelectric conversion cells each including the circuit portion 30 and the photoelectric conversion unit 28 are integrated in a one-dimensional or two-dimensional matrix pattern.

The solid state imaging device configured by applying the photoelectric converter according to the second embodiment has a different circuit configuration of each pixel Cᵢⱼ but, like FIG. 31, includes: multiple word lines WLᵢ (where i=1 to m, and m is an integer) disposed in the row direction; multiple bit lines BLⱼ (where j=1 to n, and n is an integer) disposed in the column direction; pixels Cᵢⱼ disposed at the intersections between the word lines WLᵢ and the bit lines BLⱼ; a vertical scanning circuit 120 connected to the multiple word lines WLᵢ; a readout circuit 160 connected to the multiple bit lines BLⱼ; and a horizontal scanning circuit 140 connected to the readout circuit 160. Note that the configuration is shown in the 3×3 matrix pattern in the configuration example of FIG. 31, but can be extended to the matrix of m×n as described above.

Note that although the circuit portion 30 has been described as a semiconductor integrated circuit disposed on the semiconductor substrate 10 in the example of FIG. 33, the circuit portion 30 can also be formed using a thin film transistor integrated circuit in which thin film transistors formed on a thin film formed on a glass substrate are integrated, for example.

As is clear from FIG. 3, also in the solid state imaging device shown in FIG. 33, the compound semiconductor thin film 24 disposed on the lower electrode layer 25 is separated mutually by an element isolation region 34 between adjacent pixel cells.

The buffer layer 36 disposed on the compound semiconductor thin film 24 and the element isolation region 34 is formed integrally all over the semiconductor substrate surface.

In FIG. 33, a VIA electrode 33 is disposed between the source/drain region 12 and the lower electrode layer 25.

Moreover, in multiple integrated pixels, the transparent electrode layer 26 is formed as a single layer planarized over the semiconductor substrate surface, and is made electrically common.

That is, the transparent electrode layer 26 becomes a cathode electrode of the photodiode (PD) which constitutes the photoelectric conversion unit 28, and is set to have a constant potential (for example, target voltage Vₜ) for applying a high electric field. Therefore, in the multiple integrated pixels, the cathode electrode of the photodiode (PD) which constitutes the photoelectric conversion unit 28 does not need to be separately formed, but is integrally formed on the semiconductor substrate surface and is made electrically common.

Also in the solid state imaging device, the stacked structure of the circuit portion 30 and the photoelectric conversion unit 28 enables the whole pixel region of the photoelectric conversion cell to be used as a substantial photoelectric conversion region. Accordingly, in a CMOS type image sensor, an aperture ratio is about 80% to 90% compared with an aperture ratio of about 30% to 40% in the case where the photoelectric conversion unit 28 is formed as a pn junction diode in the semiconductor substrate, thus achieving a considerable improvement effect.

In the solid state imaging device shown in FIG. 33, there is no amplifying function for every pixel, reflecting the difference in the circuit configuration.

Meanwhile, the configuration of the photoelectric conversion unit 28 is the same as that in the solid state imaging device configured by applying the photoelectric converter according to the first embodiment. Thus, the step of forming the compound semiconductor thin film of chalcopyrite structure shown in FIGS. 17A and 17B, the photoelectric conversion characteristics shown in FIG. 22, the wavelength characteristics of the quantum efficiency of the compound semiconductor thin film (CIGS thin film) shown in FIG. 23, the optical absorption characteristics shown in FIG. 24, the composition ratio dependence of the band gap energy of the compound semiconductor thin film shown in FIG. 25, and the like are all the same as those in the solid state imaging device configured by applying the photoelectric converter according to the second embodiment of the present invention. Therefore, description thereof is omitted.

Note that the transparent electrode layer (ZnO film) 26 becomes equipotential, and thus does not need to be separately formed for each pixel. However, in the case of a large-capacity area sensor or the like with which resistivity becomes a problem, electrodes each made of aluminum or the like may be disposed in a mesh or stripe pattern on the transparent electrode layer 26 at a fixed pitch to such extent that the aperture ratio of the pixel is not affected.

Also, the configuration having the buffer layer 36 has been described above as an embodiment. Although the leakage current can be reduced by the buffer layer 36, the present invention is not limited thereto. The present invention is applicable to a configuration in which an electrode layer is provided, without the buffer layer, on the compound semiconductor thin film (CIGS) layer.

The second embodiment can provide a photoelectric converter and a process for producing the same, which achieve a high S/N ratio by applying a high electric field to the photoelectric conversion unit using the chalcopyrite semiconductor to cause the multiplication of charges by impact ionization, and by improving dark current characteristics to considerably improve detection efficiency even at low luminance.

The second embodiment can provide a photoelectric converter and a process for producing the same, in which improvement in dark current characteristics leads to observation of a multiplication phenomenon that has never heretofore been observed, thus enabling even low luminance light to be detected.

The second embodiment can provide a solid state imaging device which achieves a high S/N ratio by applying a high electric field to the photoelectric conversion unit using the chalcopyrite semiconductor to cause the multiplication of charges by impact ionization, and by improving dark current characteristics to considerably improve detection efficiency even at low luminance.

The second embodiment can provide a solid state imaging device in which improvement in dark current characteristics leads to observation of a multiplication phenomenon that has never heretofore been observed, thus enabling even low illuminate light to be detected.

### Other Embodiments

The present invention has been described through the first and second embodiments of the present invention. However, it should be understood that the present invention is limited to the description and drawings which constitute a part of this disclosure. From this disclosure, various alternative embodiments, examples and operational technologies will become apparent to those skilled in the art.

In the photoelectric converter and the process for producing the same and the solid state imaging device according to the first and second embodiments of the present invention, (Cu(In_{X}, Ga_{1-X})Se₂ (0≦X≦1)) is used as the compound semiconductor thin film having the chalcopyrite structure in the photoelectric conversion unit. However, the present invention is not limited thereto.

As the CIGS thin film applied to the compound semiconductor thin film, one having a composition of Cu(In_{X}, Ga_{1-X})(Se_{Y}, S_{1-Y}) (where 0≦X≦1 and 0≦Y≦1) is also known, and a CIGS thin film having such a composition may be used.

As the compound semiconductor thin film of chalcopyrite structure, are also applicable other compound semiconductor thin films such as CuAlS₂, CuAlSe₂, CuAlTe₂, CuGaS₂, CuGaSe₂, CuGaTe₂, CuInS₂, CuInSe₂, CuInTe₂, AgAlS₂, AgAlSe₂, AgAlTe₂, AgGaS₂, AgGaSe₂, AgGaTe₂, AgInS₂, AgInSe₂, and AgInTe₂.

Also, although the configurations each having the buffer layer have been described above as embodiments, the present invention is not limited thereto. The present invention is applicable to a configuration in which an electrode layer is provided, without the buffer layer, on the compound semiconductor thin film (CIGS) layer.

As described above, the present invention includes various embodiments and the like which are not described herein, as a matter of course. Therefore, a technical scope of the present invention is only determined by constituent features of the invention according to a scope of claims appropriate for the above descriptions.

The photoelectric converter and the solid state imaging device of the present invention have high sensitivity also to the near infrared light, and thus are applicable to an image sensor for a security camera (a camera for sensing the visible light during the day and sensing the near infrared light at night), a personal authentication camera (a camera for personal authentication with near infrared light which is not affected by outside light) or an in-vehicle camera (a camera mounted in a car for visual aid at night, distant visual field securing, etc.), and also to an image sensor for detecting near infrared light for medical applications, a photodetection device (photodetector) in a wide wavelength region, an avalanche photodiode, and the like.

What is claimed is:

1. A photoelectric converter comprising:
a circuit portion formed on a substrate;
a lower electrode layer disposed on the circuit portion;
a first photoelectric conversion layer formed of a compound semiconductor thin film of chalcopyrite structure and disposed on the lower electrode layer;
a transparent electrode layer disposed on the first photoelectric conversion layer;
an interlayer insulating layer formed on the transparent electrode layer;
electrodes formed on the interlayer insulating layer; and
a second photoelectric conversion layer formed of a zinc-oxide-based compound semiconductor thin film formed on the electrodes and electrically connected to the electrodes, wherein
the lower electrode layer, the first photoelectric conversion layer, the transparent electrode layer, the interlayer insulating layer, and the second photoelectric conversion layer are sequentially stacked on the circuit portion, and
with application of a reverse bias voltage between the transparent electrode layer and the lower electrode layer and between the electrodes, the second photoelectric conversion layer photoelectrically converts ultraviolet region light and the first photoelectric conversion layer photoelectrically converts light having a wavelength longer than that of the ultraviolet region.

2. The photoelectric converter of claim 1, wherein:
the circuit portion includes a transistor having a gate connected to the lower electrode layer.

3. The photoelectric converter of claim 1, wherein:
the circuit portion includes a transistor having one of a source and a drain connected to the lower electrode layer.

4. The photoelectric converter of claim 1, wherein:
the compound semiconductor thin film of chalcopyrite structure is formed of Cu(In_{X}, Ga_{1-X})Se₂ (0≦X≦1).

5. The photoelectric converter of claim 1, wherein:
the transparent electrode layer includes a non-doped ZnO film provided on the compound semiconductor thin film and an n-type ZnO film provided on the non-doped ZnO film.

6. The photoelectric converter of claim 1, wherein:
the photoelectric converter is a photosensor having sensitivity also in a near infrared light region.

7. The photoelectric converter of claim 1, wherein:
the compound semiconductor thin film includes a high-resistivity layer in a surface of the compound semiconductor thin film.

8. The photoelectric converter of claim 1, wherein:
the electrodes form ohmic contacts with the second photoelectric conversion layer.

9. The photoelectric converter of claim 8, wherein:
the electrodes are each mainly made of a metal having a work function of not less than 4.3 eV and not more than 5.2 eV.

10. The photoelectric converter of claim 8, wherein:
the second photoelectric conversion layer has no particular crystalline orientation.

11. The photoelectric converter of claim 1, wherein:
the electrodes are each partially covered with the second photoelectric conversion layer.

12. The photoelectric converter of claim 1, wherein:
the second photoelectric conversion layer is formed of Mg_{X}Zn_{1-X}O (0≦X≦0.7).

13. A process for producing a photoelectric converter, comprising:
a first step of maintaining a substrate temperature at a first temperature and maintaining a composition ratio of (Cu/(In+Ga)) at 0 in an excessive state of group III elements;
a second step of changing the substrate temperature to a second temperature higher than the first temperature, maintaining the second temperature, and shifting the excessive state of group III elements to an excessive state of Cu elements in which the composition ratio of (Cu/(In+Ga)) is not less than 1.0; and
a third step of shifting the excessive state of Cu elements in which the composition ratio of (Cu/(In+Ga)) is not less than 1.0 to an excessive state of the group III elements in which the composition ratio of (Cu/(In+Ga)) is not more than 1.0, wherein
the third step includes a first period in which the substrate temperature is maintained at the second temperature, and a second period in which the substrate temperature is changed from the second temperature to a third temperature lower than the first temperature and maintained at the third temperature, so that the compound semiconductor thin film of chalcopyrite structure is formed.

14. The process for producing a photoelectric converter of claim 13, wherein:
the compound semiconductor thin film of chalcopyrite structure is formed of Cu(In_{X}, Ga_{1-X})Se₂ (0≦X≦1).

15. The process for producing a photoelectric converter of claim 13, wherein:
the third temperature is not less than 300° C. and not more than 400° C.

16. The process for producing a photoelectric converter of claim 13, wherein:
the second temperature is not more than 550° C.

17. The process for producing a photoelectric converter of claim 13, wherein:
the composition ratio of (Cu/(In+Ga)) is 0.5 to 1.0.

18. The process for producing a photoelectric converter of claim 13, wherein:
the compound semiconductor thin film includes a high-resistivity layer in a surface of the compound semiconductor thin film.

19. A solid state imaging device comprising:
a circuit portion formed on a substrate;
lower electrode layers disposed on the circuit portion and separated from each other between pixels adjacent to each other in one of a column direction and a row direction;
first photoelectric conversion layers each formed of a compound semiconductor thin film of chalcopyrite structure, disposed on the respective lower electrode layers, and separated from each other between the adjacent pixels in one of the column direction and the row direction;
a transparent electrode layer disposed on the first photoelectric conversion layers and having a planarized structure over the adjacent pixels;
an interlayer insulating layer formed on the transparent electrode layer;
electrodes formed on the interlayer insulating layer; and
second photoelectric conversion layers each formed of a zinc-oxide-based compound semiconductor thin film formed on the electrodes and electrically connected to the electrodes, wherein
the lower electrode layers, the first photoelectric conversion layers, the transparent electrode layer, the interlayer insulating layer, and the second photoelectric conversion layers are sequentially stacked on the circuit portion, and
each of the second photoelectric conversion layers photoelectrically converts ultraviolet region light and a corresponding one of the first photoelectric conversion layers photoelectrically converts light having a wavelength longer than that of the ultraviolet region, with application of a reverse bias voltage between the transparent electrode layer and a corresponding one of the lower electrode layers and between the corresponding electrodes.

20. The solid state imaging device of claim 19, wherein:
the circuit portion includes a transistor having a gate connected to each of the lower electrode layers.

21. The solid state imaging device of claim 19, wherein:
the circuit portion includes a transistor having one of a source and a drain connected to each of the lower electrode layers.

22. The solid state imaging device of claim 19, wherein:
the circuit portion is integrated with the lower electrode layers, the compound semiconductor thin films and the transparent electrode layer, which are sequentially stacked on the circuit portion.

23. The solid state imaging device of claim 19, wherein:
the transparent electrode layer is formed as a single layer planarized over a surface of the substrate.

24. The solid state imaging device of claim 19, wherein:
the compound semiconductor thin films of chalcopyrite structure are each formed of Cu(In_{X}, Ga_{1-X})Se₂ (0≦X≦1).

25. The solid state imaging device of claim 19, wherein:
the transparent electrode layer includes a non-doped ZnO film provided on an interface with the compound semiconductor thin films and an n-type ZnO film provided on the non-doped ZnO film.

26. The solid state imaging device of claim 19, wherein:
the solid state imaging device is a photosensor having sensitivity also in a near infrared light region.

27. The solid state imaging device of claim 19, wherein:
the solid state imaging device includes a color filter on the transparent electrode layer.

28. A solid state imaging device comprising:
a plurality of word lines WLᵢ (where i=1 to m, and m is an integer) disposed in a row direction;
a plurality of bit lines BLⱼ (where j=1 to n, and n is an integer) disposed in a column direction;
photodiodes including
lower electrode layers, respectively,
compound semiconductor thin films of chalcopyrite structure disposed on the lower electrode layers, respectively, and
a transparent electrode layer disposed on the compound semiconductor thin films; and
pixels disposed at intersections of the plurality of word lines WLᵢ and the plurality of bit lines BLⱼ, wherein
the lower electrode layers, the compound semiconductor thin films and the transparent electrode layer are sequentially stacked, and
with application of a reverse bias voltage between the transparent electrode layer and each of the lower electrode layers, impact ionization is caused in a corresponding one of the compound semiconductor thin films of chalcopyrite structure, and thereby induces the multiplication of charges generated by photoelectric conversion.

29. The solid state imaging device of claim 28, further comprising:
a vertical scanning circuit connected to the plurality of word lines WLᵢ;
a readout circuit connected to the plurality of bit lines BLⱼ; and
a horizontal scanning circuit connected to the readout circuit.

30. The solid state imaging device of claim 28, wherein:
each of the pixels includes a selection transistor having a gate connected to a corresponding one of the word lines WLᵢ (where i=1 to m, and m is an integer) and a drain connected to a corresponding one of the bit lines BLⱼ (where j=1 to n, and n is an integer).
